(19) United States
(12) Patent Application Publication
(10) Pub. No.: US 2009/0214779 A1
(43) Pub. Date: Aug. 27, 2009

(54) MULTIPLE AMPOULE DELIVERY SYSTEMS

(76) Inventors: Demetrius Sarigiannis, Grand Island, NY (US); Cynthia A. Hoover, Grand Island, NY (US); Michael Joseph Krause, Orchard Park, NY (US); Edward Pryor, San Antonio, TX (US); Stephen Chesters, Allen, TX (US); Ronald Spohn, Getzville, NY (US)

Correspondence Address: PRAXAIR, INC.;LAW DEPARTMENT - M1 557, 39 OLD RIDGEBURY ROAD, DANBURY, CT, 06810-5113, US

(21) Appl. No.: 12/369,810

(22) Filed: Feb. 12, 2009

Related U.S. Application Data
(60) Provisional application No. 61/030,578, filed on Feb. 22, 2008.

(51) Int. Cl. C23C 16/44; C23C 16/54; B05C 11/00

(52) U.S. Cl. 427/248.1; 118/715; 118/725; 118/696

(57) ABSTRACT

This invention relates to an integrated vapor or liquid phase reagent dispensing apparatus having a plurality of vessels and a plurality of carrier or inert gas feed/vapor or liquid phase reagent delivery manifolds, that may be used for continuously dispensing vapor or liquid phase reagents such as precursors for deposition of materials in the manufacture of semiconductor materials and devices.

### RELATED APPLICATIONS

This invention claims priority from provisional U.S. Patent Application Ser. No. 61/030,578, filed Feb. 22, 2008, which is incorporated herein by reference. This application is related to U.S. patent application Ser. No. (21747-R1), filed on an even date herewith, U.S. patent application Ser. No. (21747-R2), filed on an even date herewith, and U.S. patent application Ser. No. (21747-R3), filed on an even date herewith, all of which are incorporated herein by reference.

### FIELD OF THE INVENTION

This invention relates to an integrated vapor or liquid phase reagent dispensing apparatus having a plurality of vessels and a plurality of carrier or inert gas feed/vapor or liquid phase reagent delivery manifolds, that may be used for continuously dispensing vapor or liquid phase reagents such as precursors for deposition of materials in the manufacture of semiconductor materials and devices.

### BACKGROUND OF THE INVENTION

High purity chemicals used in the semiconductor and pharmaceutical industries require special packaging to maintain their purity in storage. This is especially true for chemicals that react with air and/or moisture in the air. Such high purity chemicals are typically supplied in containers such as bubblers or ampoules.

Modern chemical vapor deposition and atomic layer deposition tools utilize bubblers or ampoules to deliver precursor chemicals to a deposition chamber. These bubblers or ampoules work by passing a carrier gas through a container of high purity precursor chemical and carrying the precursor vapor along with the gas to the deposition chamber.

As integrated circuits have decreased in size, so have the dimensions of the internal components or features. As the sizes decreased, the need for more pure chemicals has correspondingly increased to minimize the effect of impurities on film quality and device performance. Suppliers therefore, must be able to not only manufacture high purity chemicals, but must also be able to deliver them in a container which will maintain the high purity.

The physical properties of the precursor chemicals along with materials of construction of the ampoules and valves dictate the maximum allowable delivery temperatures that can be used. Some of the precursor chemical properties that make them challenging to handle and deliver include, for example, their exothermic reactivity with moisture and oxygen in the air. This can lead to, in the case of a large spill, the evolution of combustible by-products and fire, and in the case of residual air in a delivery line, particulates that can contaminate the delivery lines and then be transferred to the wafer surface during process, destroying the electronic devices. The limited thermal stability of precursor chemicals leads to, in heated ampoules, a gradual build-up of impurities in the ampoule (heel) that can reduce vapor pressure and/or contaminate the process, and decomposition in the gas lines and valves of the precursor chemical delivery manifold, resulting in particles contaminating the process.

It is also important to know when the precursor chemical inside of the ampoule is close to running out so that it can be changed prior to the next chemical vapor deposition or atomic layer deposition run. If the ampoule should run dry in the middle of a cycle, the entire batch of wafers will be ruined resulting in a potential loss of millions of dollars. It is therefore desirable to leave as little precursor chemical as possible inside of the ampoule to avoid wasting the valuable liquid precursor chemical. As the cost of chemical precursors increase, wasting as little chemical as possible becomes more important.

The consumption rate of the deposition process and the size of the ampoule are determinative of the frequency for changing out an ampoule. The change-out steps can be very time consuming and include: (i) closing the ampoule and cycle purging the lines at a temperature sufficient to remove residual precursor chemical; (ii) cooling the ampoule to room temperature, removing the used ampoule and replacing it with a fresh one; (iii) cycle purging the system at room temperature to remove residual air in the connection legs; (iv) slowly heating the ampoule (and it's valves) up to a desired temperature (slow heating is important to avoid decomposing the material); ampoule is heated to just above melting point of the precursor chemical; ampoule is slowly ramped from melting to operating temperature; and qualification of the new material.

In the case of precursor chemicals with low thermal stability and/or the property of being a solid at room temperature, the implementation of a bulk delivery system can be challenging and impractical. For example, the challenges include having to heat and melt a large quantity of material in the reservoir and heat tracing extensive lengths of precursor chemical distribution lines to ensure the precursor chemical remains a liquid; impurity build-up in the ampoule as the impurities concentrate in the vessel from fill to fill; and thermal decomposition of the precursor chemical in idle, heated distribution lines.

It would be desirable in the art to provide a vapor or liquid phase reagent dispensing apparatus which is capable of operating with minimum downtime associated with change-out of ampoules. It would be desirable in the art to provide a vapor or liquid phase reagent dispensing apparatus which is capable of maintaining high purity of the precursor chemical and also increasing the usage of the precursor chemical in the apparatus, and correspondingly reducing waste thereof.

Also, it would be desirable in the art to provide a vapor or liquid phase reagent dispensing apparatus which would be transparent to the process tools that the apparatus is hooked up to. In other words, the tool operator should not have to make modifications to the tool for the vapor or liquid phase reagent dispensing apparatus to work properly.

### SUMMARY OF THE INVENTION

This invention relates in part to an integrated vapor phase reagent dispensing apparatus comprising:

a plurality of vessels, each vessel comprising a top wall member, a sidewall member and a bottom wall member configured to form an internal vessel compartment to hold a source chemical up to a fill level and to additionally define an inner gas volume above the fill level; a portion of the top wall member having a carrier gas feed inlet opening through which carrier gas can be fed into said inner gas volume above the fill level to cause vapor of said source chemical to become entrained in said carrier gas to produce vapor phase reagent; and a portion of the top wall member having a vapor phase reagent outlet opening through which said vapor phase reagent can be dispensed from said vessel;

a plurality of carrier gas feed/vapor phase reagent delivery manifolds, each of said carrier gas feed/vapor phase reagent delivery manifolds interconnected with each other; each vessel connected to at least one carrier gas feed/vapor phase reagent delivery manifold; each carrier gas feed/vapor phase reagent delivery manifold comprising a carrier gas feed line and a vapor phase reagent discharge line; said carrier gas feed line extending from the carrier gas feed inlet opening upwardly and exteriorly from the top wall member for delivery of carrier gas into said inner gas volume above the fill level, the carrier gas feed line containing one or more carrier gas flow control valves therein for control of flow of the carrier gas therethrough; and said vapor phase reagent discharge line extending from the vapor phase reagent outlet opening upwardly and exteriorly from the top wall member for removal of vapor phase reagent from said inner gas volume above the fill level, the vapor phase reagent discharge line optionally containing one or more vapor phase reagent flow control valves therein for control of flow of the vapor phase reagent therethrough; and

one or more controllers for directing communication with each of said carrier gas feed/vapor phase reagent delivery manifolds and each of said vessels, in such a way that each of said carrier gas feed/vapor phase reagent delivery manifolds are operable independently of one another, and each of said vessels are operable independently of one another.

This invention also relates in part to an integrated vapor phase reagent dispensing apparatus comprising:

a plurality of vessels, each vessel comprising a top wall member, a sidewall member and a bottom wall member configured to form an internal vessel compartment to hold a source chemical up to a fill level and to additionally define an inner gas volume above the fill level; a portion of the top wall member having a carrier gas feed inlet opening through which carrier gas can be fed into said inner gas volume above the fill level to cause vapor of said source chemical to become entrained in said carrier gas to produce vapor phase reagent; and a portion of the top wall member having a vapor phase reagent outlet opening through which said vapor phase reagent can be dispensed from said vessel;

a plurality of carrier gas feed/vapor phase reagent delivery manifolds, each of said carrier gas feed/vapor phase reagent delivery manifolds interconnected with each other; each vessel connected to at least one carrier gas feed/vapor phase reagent delivery manifold; each carrier gas feed/vapor phase reagent delivery manifold comprising a carrier gas feed line and a vapor phase reagent discharge line; said carrier gas feed line extending from the carrier gas feed inlet opening upwardly and exteriorly from the top wall member for delivery of carrier gas into said inner gas volume above the fill level, the carrier gas feed line containing one or more carrier gas flow control valves therein for control of flow of the carrier gas therethrough; and said vapor phase reagent discharge line extending from the vapor phase reagent outlet opening upwardly and exteriorly from the top wall member for removal of vapor phase reagent from said inner gas volume above the fill level, the vapor phase reagent discharge line optionally containing one or more vapor phase reagent flow control valves therein for control of flow of the vapor phase reagent therethrough;

a plurality of sourcing gas manifolds; each of said sourcing gas manifolds interconnected with each other; each sourcing gas manifold connected to at least one carrier gas feed/vapor phase reagent delivery manifold; each sourcing gas manifold comprising a carrier gas feed line continuous with said carrier gas feed line of said carrier gas feed/vapor phase reagent delivery manifold; the carrier gas feed line containing one or more carrier gas flow control valves therein for control of flow of the carrier gas therethrough, and a pressure transducer for monitoring and controlling the pressure of the sourcing gas manifold; and

one or more controllers for directing communication with each of said sourcing gas manifolds, each of said carrier gas feed/vapor phase reagent delivery manifolds and each of said vessels, in such a way that each of said sourcing gas manifolds are operable independently of one another, each of said carrier gas feed/vapor phase reagent delivery manifolds are operable independently of one another, and each of said vessels are operable independently of one another.

This invention further relates to a method for delivery of a vapor phase reagent to a deposition chamber comprising:

(a) providing an integrated vapor phase reagent dispensing apparatus comprising:

a plurality of vessels, each vessel comprising a top wall member, a sidewall member and a bottom wall member configured to form an internal vessel compartment to hold a source chemical up to a fill level and to additionally define an inner gas volume above the fill level; a portion of the top wall member having a carrier gas feed inlet opening through which carrier gas can be fed into said inner gas volume above the fill level to cause vapor of said source chemical to become entrained in said carrier gas to produce vapor phase reagent; and a portion of the top wall member having a vapor phase reagent outlet opening through which said vapor phase reagent can be dispensed from said vessel;

a plurality of carrier gas feed/vapor phase reagent delivery manifolds, each of said carrier gas feed/vapor phase reagent delivery manifolds interconnected with each other; each vessel connected to at least one carrier gas feed/vapor phase reagent delivery manifold; each carrier gas feed/vapor phase reagent delivery manifold comprising a carrier gas feed line and a vapor phase reagent discharge line; said carrier gas feed line extending from the carrier gas feed inlet opening upwardly and exteriorly from the top wall member for delivery of carrier gas into said inner gas volume above the fill level, the carrier gas feed line containing one or more carrier gas flow control valves therein for control of flow of the carrier gas therethrough; and said vapor phase reagent discharge line extending from the vapor phase reagent outlet opening upwardly and exteriorly from the top wall member for removal of vapor phase reagent from said inner gas volume above the fill level, the vapor phase reagent discharge line optionally containing one or more vapor phase reagent flow control valves therein for control of flow of the vapor phase reagent therethrough; and

one or more controllers for directing communication with each of said carrier gas feed/vapor phase reagent delivery manifolds and each of said vessels, in such a way that each of said carrier gas feed/vapor phase reagent delivery manifolds are operable independently of one another, and each of said vessels are operable independently of one another;

adding source chemical to one or more of said vessels;

heating the source chemical in one or more of said vessels to a temperature sufficient to vaporize the source chemical to provide vapor phase reagent;

feeding a carrier gas into one or more of said vessels through said carrier gas feed line;

withdrawing the vapor phase reagent and carrier gas from one of said vessels, independently of any other of said vessels, through said vapor phase reagent discharge line; and

feeding the vapor phase reagent and carrier gas into said deposition chamber.

This invention yet further relates in part to an integrated vapor phase reagent dispensing apparatus comprising:

a plurality of vessels, each vessel comprising a top wall member, a sidewall member and a bottom wall member configured to form an internal vessel compartment to hold a source chemical up to a fill level and to additionally define an inner gas volume above the fill level; a portion of the top wall member having a carrier gas feed inlet opening comprising a bubbler tube that extends through the inner gas volume into the source chemical and through which said carrier gas can be bubbled into the source chemical to cause at least a portion of source chemical vapor to become entrained in said carrier gas to produce a flow of vapor phase reagent to said inner gas volume above the fill level, said bubbler tube having an inlet end adjacent to the top wall member and an outlet end adjacent to the bottom wall member; and a portion of the top wall member having a vapor phase reagent outlet opening through which said vapor phase reagent can be dispensed from said vessel; and

a plurality of carrier gas feed/vapor phase reagent delivery manifolds, each of said carrier gas feed/vapor phase reagent delivery manifolds interconnected with each other; each vessel connected to at least one carrier gas feed/vapor phase reagent delivery manifold; each carrier gas feed/vapor phase reagent delivery manifold comprising a carrier gas feed line and a vapor phase reagent discharge line; said carrier gas feed line extending from the carrier gas feed inlet opening upwardly and exteriorly from the top wall member for delivery of carrier gas into said inner gas volume above the fill level, the carrier gas feed line containing one or more carrier gas flow control valves therein for control of flow of the carrier gas therethrough; and said vapor phase reagent discharge line extending from the vapor phase reagent outlet opening upwardly and exteriorly from the top wall member for removal of vapor phase reagent from said inner gas volume above the fill level, the vapor phase reagent discharge line optionally containing one or more vapor phase reagent flow control valves therein for control of flow of the vapor phase reagent therethrough; and

one or more controllers for directing communication with each of said carrier gas feed/vapor phase reagent delivery manifolds and each of said vessels, in such a way that each of said carrier gas feed/vapor phase reagent delivery manifolds are operable independently of one another, and each of said vessels are operable independently of one another.

This invention also relates in part to an integrated vapor phase reagent dispensing apparatus comprising:

a plurality of vessels, each vessel comprising a top wall member, a sidewall member and a bottom wall member configured to form an internal vessel compartment to hold a source chemical up to a fill level and to additionally define an inner gas volume above the fill level; a portion of the top wall member having a carrier gas feed inlet opening comprising a bubbler tube that extends through the inner gas volume into the source chemical and through which said carrier gas can be bubbled into the source chemical to cause at least a portion of source chemical vapor to become entrained in said carrier gas to produce a flow of vapor phase reagent to said inner gas volume above the fill level, said bubbler tube having an inlet end adjacent to the top wall member and an outlet end adjacent to the bottom wall member; and a portion of the top wall member having a vapor phase reagent outlet opening through which said vapor phase reagent can be dispensed from said vessel;

a plurality of carrier gas feed/vapor phase reagent delivery manifolds, each of said carrier gas feed/vapor phase reagent delivery manifolds interconnected with each other; each vessel connected to at least one carrier gas feed/vapor phase reagent delivery manifold; each carrier gas feed/vapor phase reagent delivery manifold comprising a carrier gas feed line and a vapor phase reagent discharge line; said carrier gas feed line extending from the carrier gas feed inlet opening upwardly and exteriorly from the top wall member for delivery of carrier gas into said inner gas volume above the fill level, the carrier gas feed line containing one or more carrier gas flow control valves therein for control of flow of the carrier gas therethrough; and said vapor phase reagent discharge line extending from the vapor phase reagent outlet opening upwardly and exteriorly from the top wall member for removal of vapor phase reagent from said inner gas volume above the fill level, the vapor phase reagent discharge line optionally containing one or more vapor phase reagent flow control valves therein for control of flow of the vapor phase reagent therethrough;

a plurality of sourcing gas manifolds; each of said sourcing gas manifolds interconnected with each other; each sourcing gas manifold connected to at least one carrier gas feed/vapor phase reagent delivery manifold; each sourcing gas manifold comprising a carrier gas feed line continuous with said carrier gas feed line of said carrier gas feed/vapor phase reagent delivery manifold; the carrier gas feed line containing one or more carrier gas flow control valves therein for control of flow of the carrier gas therethrough, and a pressure transducer for monitoring and controlling the pressure of the sourcing gas manifold; and

one or more controllers for directing communication with each of said sourcing gas manifolds, each of said carrier gas feed/vapor phase reagent delivery manifolds and each of said vessels, in such a way that each of said sourcing gas manifolds are operable independently of one another, each of said carrier gas feed/vapor phase reagent delivery manifolds are operable independently of one another, and each of said vessels are operable independently of one another.

This invention further relates in part to a method for delivery of a vapor phase reagent to a deposition chamber comprising:

(a) providing a integrated vapor phase reagent dispensing apparatus comprising:

a plurality of vessels, each vessel comprising a top wall member, a sidewall member and a bottom wall member configured to form an internal vessel compartment to hold a source chemical up to a fill level and to additionally define an inner gas volume above the fill level; a portion of the top wall member having a carrier gas feed inlet opening comprising a bubbler tube that extends through the inner gas volume into the source chemical and through which said carrier gas can be bubbled into the source chemical to cause at least a portion of source chemical vapor to become entrained in said carrier gas to produce a flow of vapor phase reagent to said inner gas volume above the fill level, said bubbler tube having an inlet end adjacent to the top wall member and an outlet end adjacent to the bottom wall member; and a portion of the top wall member having a vapor phase reagent outlet opening through which said vapor phase reagent can be dispensed from said vessel; and

a plurality of carrier gas feed/vapor phase reagent delivery manifolds, each of said carrier gas feed/vapor phase reagent delivery manifolds interconnected with each other; each vessel connected to at least one carrier gas feed/vapor phase reagent delivery manifold; each carrier gas feed/vapor phase reagent delivery manifold comprising a carrier gas feed line and a vapor phase reagent discharge line; said carrier gas feed line extending from the carrier gas feed inlet opening upwardly and exteriorly from the top wall member for delivery of carrier gas into said inner gas volume above the fill level, the carrier gas feed line containing one or more carrier gas flow control valves therein for control of flow of the carrier gas therethrough; and said vapor phase reagent discharge line extending from the vapor phase reagent outlet opening upwardly and exteriorly from the top wall member for removal of vapor phase reagent from said inner gas volume above the fill level, the vapor phase reagent discharge line optionally containing one or more vapor phase reagent flow control valves therein for control of flow of the vapor phase reagent therethrough; and

one or more controllers for directing communication with each of said carrier gas feed/vapor phase reagent delivery manifolds and each of said vessels, in such a way that each of said carrier gas feed/vapor phase reagent delivery manifolds are operable independently of one another, and each of said vessels are operable independently of one another;

adding source chemical to one or more of said vessels;

heating the source chemical in one or more of said vessels to a temperature sufficient to vaporize the source chemical to provide vapor phase reagent;

feeding a carrier gas into one or more of said vessels through said carrier gas feed line and said bubbler tube;

withdrawing the vapor phase reagent and carrier gas from one of said vessels, independently of any other of said vessels, through said vapor phase reagent discharge line; and

feeding the vapor phase reagent and carrier gas into said deposition chamber.

This invention yet further relates in part to an integrated liquid phase reagent dispensing apparatus comprising:

a plurality of vessels, each vessel comprising a top wall member, a sidewall member and a bottom wall member configured to form an internal vessel compartment to hold a source chemical up to a fill level and to additionally define an inner gas volume above the fill level; a portion of the top wall member having an inert gas feed inlet opening through which said inert gas can be fed into the inner gas volume above the fill level to pressurize the inner gas volume above the fill level; and a portion of the top wall member having a liquid phase reagent outlet opening comprising a diptube that extends through the inner gas volume into the source chemical and through which liquid phase reagent can be dispensed from said apparatus, said diptube having an outlet end adjacent to the top wall member and an inlet end adjacent to the bottom wall member;

a plurality of inert gas feed/liquid phase reagent delivery manifolds, each of said inert gas feed/liquid phase reagent delivery manifolds interconnected with each other; each vessel connected to at least one inert gas feed/liquid phase reagent delivery manifold; each inert gas feed/liquid phase reagent delivery manifold comprising an inert gas feed line and a liquid phase reagent discharge line; said inert gas feed line extending from the inert gas feed inlet opening upwardly and exteriorly from the top wall member for delivery of inert gas into said inner gas volume above the fill level, the inert gas feed line containing one or more inert gas flow control valves therein for control of flow of the inert gas therethrough; and said liquid phase reagent discharge line extending from the liquid phase reagent outlet opening upwardly and exteriorly from the top wall member for removal of liquid phase reagent from said vessel, the liquid phase reagent discharge line optionally containing one or more liquid phase reagent flow control valves therein for control of flow of the liquid phase reagent therethrough; and

one or more controllers for directing communication with each of said inert gas feed/liquid phase reagent delivery manifolds and each of said vessels, in such a way that each of said inert gas feed/liquid phase reagent delivery manifolds are operable independently of one another, and each of said vessels are operable independently of one another.

This invention also relates in part to an integrated liquid phase reagent dispensing apparatus comprising:

a plurality of vessels, each vessel comprising a top wall member, a sidewall member and a bottom wall member configured to form an internal vessel compartment to hold a source chemical up to a fill level and to additionally define an inner gas volume above the fill level; a portion of the top wall member having an inert gas feed inlet opening through which said inert gas can be fed into the inner gas volume above the fill level to pressurize the inner gas volume above the fill level; and a portion of the top wall member having a liquid phase reagent outlet opening comprising a diptube that extends through the inner gas volume into the source chemical and through which liquid phase reagent can be dispensed from said apparatus, said diptube having an outlet end adjacent to the top wall member and an inlet end adjacent to the bottom wall member;

a plurality of inert gas feed/liquid phase reagent delivery manifolds, each of said inert gas feed/liquid phase reagent delivery manifolds interconnected with each other; each vessel connected to at least one inert gas feed/liquid phase reagent delivery manifold; each inert gas feed/liquid phase reagent delivery manifold comprising an inert gas feed line and a liquid phase reagent discharge line; said inert gas feed line extending from the inert gas feed inlet opening upwardly and exteriorly from the top wall member for delivery of inert gas into said inner gas volume above the fill level, the inert gas feed line containing one or more inert gas flow control valves therein for control of flow of the inert gas therethrough; and said liquid phase reagent discharge line extending from the liquid phase reagent outlet opening upwardly and exteriorly from the top wall member for removal of liquid phase reagent from said vessel, the liquid phase reagent discharge line optionally containing one or more liquid phase reagent flow control valves therein for control of flow of the liquid phase reagent therethrough;

a plurality of sourcing gas manifolds, each of said sourcing gas manifolds interconnected with each other; each sourcing gas manifold connected to at least one inert gas feed/liquid phase reagent delivery manifold; each sourcing gas manifold comprising an inert gas feed line continuous with said inert gas feed line of said inert gas feed/liquid phase reagent delivery manifold; the inert gas feed line containing one or more inert gas flow control valves therein for control of flow of the inert gas therethrough, and a pressure transducer for monitoring and controlling the pressure of the sourcing gas manifold; and

one or more controllers for directing communication with each of said inert gas feed/liquid phase reagent delivery manifolds and each of said vessels, in such a way that each of said inert gas feed/liquid phase reagent delivery manifolds are operable independently of one another, and each of said vessels are operable independently of one another.

This invention further relates in part to a method for delivery of a vapor phase reagent to a deposition chamber comprising:

(a) providing an integrated liquid phase reagent dispensing apparatus comprising:

a plurality of vessels, each vessel comprising a top wall member, a sidewall member and a bottom wall member configured to form an internal vessel compartment to hold a source chemical up to a fill level and to additionally define an inner gas volume above the fill level; a portion of the top wall member having an inert gas feed inlet opening through which said inert gas can be fed into the inner gas volume above the fill level to pressurize the inner gas volume above the fill level; and a portion of the top wall member having a liquid phase reagent outlet opening comprising a diptube that extends through the inner gas volume into the source chemical and through which liquid phase reagent can be dispensed from said apparatus, said diptube having an outlet end adjacent to the top wall member and an inlet end adjacent to the bottom wall member;

a plurality of inert gas feed/liquid phase reagent delivery manifolds, each of said inert gas feed/liquid phase reagent delivery manifolds interconnected with each other; each vessel connected to at least one inert gas feed/liquid phase reagent delivery manifold; each inert gas feed/liquid phase reagent delivery manifold comprising an inert gas feed line and a liquid phase reagent discharge line; said inert gas feed line extending from the inert gas feed inlet opening upwardly and exteriorly from the top wall member for delivery of inert gas into said inner gas volume above the fill level, the inert gas feed line containing one or more inert gas flow control valves therein for control of flow of the inert gas therethrough; and said liquid phase reagent discharge line extending from the liquid phase reagent outlet opening upwardly and exteriorly from the top wall member for removal of liquid phase reagent from said vessel, the liquid phase reagent discharge line optionally containing one or more liquid phase reagent flow control valves therein for control of flow of the liquid phase reagent therethrough; and

one or more controllers for directing communication with each of said inert gas feed/liquid phase reagent delivery manifolds and each of said vessels, in such a way that each of said inert gas feed/liquid phase reagent delivery manifolds are operable independently of one another, and each of said vessels are operable independently of one another;

adding source chemical to one or more of said vessels;

optionally heating a solid source chemical in one or more of said vessels to a temperature sufficient to melt the solid source chemical to provide liquid phase reagent;

feeding an inert gas into one or more of said vessels through said inert gas feed line;

withdrawing liquid phase reagent from one of said vessels, independently of any other of said vessels, through said diptube and said liquid phase reagent discharge line;

providing a vaporization apparatus comprising:

a vessel which comprises a top wall member, a sidewall member and a bottom wall member configured to form an internal vessel compartment to vaporize the liquid phase reagent;

said liquid phase reagent discharge line connecting the integrated liquid phase reagent dispensing apparatus to said vaporization apparatus;

a portion of the vaporization apparatus having a carrier gas feed inlet opening through which carrier gas can be fed into said vaporization apparatus to cause vapor of said liquid phase reagent to become entrained in said carrier gas to produce vapor phase reagent;

a portion of the vaporization apparatus having a vapor phase reagent outlet opening through which said vapor phase reagent can be dispensed from said vaporization apparatus;

a carrier gas feed line extending from the carrier gas feed inlet opening upwardly and exteriorly from the vaporization apparatus for delivery of carrier gas into said vaporization apparatus, the carrier gas feed line containing one or more carrier gas flow control valves therein for control of flow of the carrier gas therethrough;

a vapor phase reagent discharge line extending from the vapor phase reagent outlet opening upwardly and exteriorly from the vaporization apparatus for removal of vapor phase reagent from said vaporization apparatus to said deposition chamber, the vapor phase reagent discharge line containing one or more vapor phase reagent flow control valves therein for control of flow of the vapor phase reagent therethrough;

feeding the liquid phase reagent into said vaporization apparatus;

heating the liquid phase reagent in said vaporization apparatus to a temperature sufficient to vaporize the liquid phase reagent to provide said vapor phase reagent;

feeding a carrier gas into said vaporization apparatus through said carrier gas feed line;

withdrawing the vapor phase reagent and carrier gas from said vaporization apparatus through said vapor phase reagent discharge line; and

feeding the vapor phase reagent and carrier gas into said deposition chamber.

This invention yet further relates in part to an integrated vapor phase reagent dispensing apparatus comprising:

a plurality of vessels, each vessel comprising a top wall member, a sidewall member and a bottom wall member configured to form an internal vessel compartment to hold a source chemical; and a portion of the top wall member having a vapor phase reagent outlet opening through which a vapor phase reagent can be dispensed from said vessel;

a plurality of vapor phase reagent delivery manifolds, each of said vapor phase reagent delivery manifolds interconnected with each other; each vessel connected to at least one vapor phase reagent delivery manifold; each vapor phase reagent delivery manifold comprising a vapor phase reagent discharge line; and said vapor phase reagent discharge line extending from the vapor phase reagent outlet opening upwardly and exteriorly from the top wall member for removal of vapor phase reagent from said vessel, the vapor phase reagent discharge line optionally containing one or more vapor phase reagent flow control valves therein for control of flow of the vapor phase reagent therethrough; and

one or more controllers for directing communication with each of said vapor phase reagent delivery manifolds and each of said vessels, in such a way that each of said vapor phase reagent delivery manifolds are operable independently of one another, and each of said vessels are operable independently of one another.

This invention also relates in part to an integrated vapor phase reagent dispensing apparatus comprising:

a plurality of vessels, each vessel comprising a top wall member, a sidewall member and a bottom wall member configured to form an internal vessel compartment to hold a source chemical; and a portion of the top wall member having a vapor phase reagent outlet opening through which a vapor phase reagent can be dispensed from said vessel;

a plurality of vapor phase reagent delivery manifolds, each of said vapor phase reagent delivery manifolds interconnected with each other; each vessel connected to at least one vapor phase reagent delivery manifold; each vapor phase reagent delivery manifold comprising a vapor phase reagent discharge line; and said vapor phase reagent discharge line extending from the vapor phase reagent outlet opening upwardly and exteriorly from the top wall member for removal of vapor phase reagent from said vessel, the vapor phase reagent discharge line optionally containing one or more vapor phase reagent flow control valves therein for control of flow of the vapor phase reagent therethrough;

a plurality of carrier gas feed manifolds; each carrier gas feed manifold connected to at least one vapor phase reagent delivery manifold; each carrier gas feed manifold comprising a carrier gas feed line; the carrier gas feed line containing one or more carrier gas flow control valves therein for control of flow of a carrier gas therethrough, and a pressure transducer for monitoring and controlling the pressure of the carrier gas feed manifold; and

one or more controllers for directing communication with each of said carrier gas feed manifolds, each of said vapor phase reagent delivery manifolds and each of said vessels, in such a way that each of said carrier gas feed manifolds are operable independently of one another, each of said vapor phase reagent delivery manifolds are operable independently of one another, and each of said vessels are operable independently of one another.

This invention further relates to a method for delivery of a vapor phase reagent to a deposition chamber comprising:

(a) providing an integrated vapor phase reagent dispensing apparatus comprising:

a plurality of vessels, each vessel comprising a top wall member, a sidewall member and a bottom wall member configured to form an internal vessel compartment to hold a source chemical; and a portion of the top wall member having a vapor phase reagent outlet opening through which a vapor phase reagent can be dispensed from said vessel;

a plurality of vapor phase reagent delivery manifolds, each of said vapor phase reagent delivery manifolds interconnected with each other; each vessel connected to at least one vapor phase reagent delivery manifold; each vapor phase reagent delivery manifold comprising a vapor phase reagent discharge line; and said vapor phase reagent discharge line extending from the vapor phase reagent outlet opening upwardly and exteriorly from the top wall member for removal of vapor phase reagent from said vessel, the vapor phase reagent discharge line optionally containing one or more vapor phase reagent flow control valves therein for control of flow of the vapor phase reagent therethrough;

a plurality of carrier gas feed manifolds; each carrier gas feed manifold connected to at least one vapor phase reagent delivery manifold; each carrier gas feed manifold comprising a carrier gas feed line; the carrier gas feed line containing one or more carrier gas flow control valves therein for control of flow of a carrier gas therethrough, and a pressure transducer for monitoring and controlling the pressure of the carrier gas feed manifold; and one or more controllers for directing communication with each of said carrier gas feed manifolds, each of said vapor phase reagent delivery manifolds and each of said vessels, in such a way that each of said carrier gas feed manifolds are operable independently of one another, each of said vapor phase reagent delivery manifolds are operable independently of one another, and each of said vessels are operable independently of one another;

adding source chemical to one or more of said vessels;

optionally heating the source chemical in one or more of said vessels to a temperature sufficient to vaporize the source chemical to provide vapor phase reagent;

withdrawing the vapor phase reagent from one of said vessels, independently of any other of said vessels, through said vapor phase reagent discharge line;

feeding a carrier gas into one or more of said vapor phase reagent delivery manifolds through said carrier gas feed line to mix with said vapor phase reagent; and

feeding the vapor phase reagent and carrier gas into said deposition chamber.

The integrated vapor or liquid phase reagent dispensing apparatus or assembly of the invention may be employed in a wide variety of process systems, including for example chemical vapor deposition systems wherein the vapor phase reagent from the supply vessel is passed to a chemical vapor deposition chamber for deposition of a material layer on a substrate therein from the source vapor.

The integrated vapor or liquid phase reagent dispensing apparatus of this invention is capable of operating continuously with minimum downtime downtime associated with change-out of ampoules, and is capable of maintaining high purity of the precursor chemical and also increasing the usage of the precursor chemical in the apparatus, and correspondingly reducing waste thereof. The integrated vapor or liquid phase reagent dispensing apparatus is transparent to the process tools that the apparatus is hooked up to. The tool operator does not have to make modifications to the tool for the integrated vapor or liquid phase reagent dispensing apparatus to work properly. The integrated vapor or liquid phase reagent dispensing apparatus or assembly of the invention maintains purity of the liquid precursor chemical, increases usage rate of the liquid or solid precursor chemical and thereby reduces waste, and increases tool utilization.

Other aspects, features and embodiments of the invention will be more fully apparent from the ensuing disclosure and appended claims.

### BRIEF DESCRIPTION OF THE DRAWINGS

FIG. 1 is a valve schematic representation of an integrated vapor or liquid phase reagent dispensing apparatus.

FIG. 2 is a schematic showing inputs and outputs to and from a programmable logic controller controlling the integrated vapor or liquid phase reagent dispensing apparatus.

FIG. 3 is a schematic showing valve notation used herein. Black legs on 3-port valves indicate the actuated leg. The flow path is always open between the white legs.

FIG. 4 is a schematic representation of a single ampoule showing valves (V-1 to V-6) and heating zones (Z-1 to Z-5).

FIG. 5 is a schematic representation of piping and instrumentation of an integrated vapor or liquid phase reagent dispensing apparatus showing valves (V-1 to V-16), pressure transducers (PTA and PTB) and heating zones (Z-1 to Z-16).

FIG. 6 is an illustrative PLC logic flow diagram representing the general basic steps and choices that the PLC would take when an operator is changing modes on each manifold.

FIG. 7 is a simplified pneumatic layout of the programmable logic controller showing an example of how pneumatic signals from the tool can be relayed to the appropriate valves on either of the active manifolds, while still allowing the programmable logic controller to control those analogous valves on the idle manifold. This configuration enables the end used to lock-out all pneumatic valves at one location on the tool.

FIG. 8 depicts a loading platform of a single ampoule.

FIG. 9 depicts a side view of an ampoule slide-out shelf showing integrated spring plate.

FIG. 10 is a schematic representation of an ampoule loading shelf to mitigate alignment and clearance issues.

FIG. 11 depicts a manifold layout of the integrated vapor or liquid phase reagent dispensing apparatus.

FIG. 12 depicts a manifold layout of the integrated vapor or liquid phase reagent dispensing apparatus showing ampoules rotated at 45° angles to reduce 90° bends in the manifolding, line lengths and spacing between ampoules.

FIG. 13 is a top-down schematic representation showing the short straight shot distance between ampoule outlets for the case of side specific ampoules facing forward (top) and a 45° (bottom).

FIG. 14 is a schematic representation of piping and instrumentation of an integrated vapor or liquid phase reagent dispensing apparatus showing valve layout with side specific ampoules.

FIG. 15 is a simplified schematic representation of an integrated vapor or liquid phase reagent dispensing apparatus showing one embodiment of carrier gas and precursor being discharged from the multiple ampoule delivery system and another embodiment of pure precursor being discharged from the multiple ampoule delivery system (neat delivery).

FIG. 16 is a schematic representation of piping and instrumentation of an integrated vapor or liquid phase reagent dispensing apparatus showing valve layout for a neat precursor delivery system.

FIG. 17 is an illustrative screen shot of a PLC screen used in an integrated vapor or liquid phase reagent dispensing apparatus.

### DETAILED DESCRIPTION OF THE INVENTION

Small quantities of organometallic precursor have typically been stored in day-containers, ampoules or bubblers to be used on chemical vapor deposition or atomic layer deposition tools. As wafers have gotten larger and the usage rate of organometallic precursors has increased, the length of time a given quantity of precursor lasts has decreased. This requires more frequent ampoule changes, leading to lower tool utilization. The standard approach so far has been to 1) go to larger ampoules and 2) go to bulk refill systems where the precursor is drawn as a liquid from a large reservoir stored in the sub-fab and sent to the smaller ampoule on the tool.

This invention is unique in that, while the bulk fill solution works for certain precursors such as TMA or TMG that have been in extensive use, many newer precursors may be solids or have low thermal stability, making a bulk fill system difficult or impossible to implement for them. In an embodiment, this invention can place two ampoules of the same or different type (e.g., both bubbler ampoules or one bubbler ampoule and one diptube ampoule) and of the same or different organometallic precursors side by side on a system. One ampoule is live while the other is offline, ready to bring online when the active one is near empty.

In addition, the multiple ampoule delivery system of this invention is designed to be controlled by a programmable logic controller that makes the semiconductor tool “see” a single ampoule system. This makes the current system a drop-in replacement for the tool vendor.

In an embodiment, this invention comprises a plurality of, e.g., two, ampoules of the same or different type (e.g., both bubbler ampoules or one bubbler ampoule and one diptube ampoule) and containing the same or different precursor with heated manifolds plumbed in parallel and sharing a common process and dump line. The manifolds are such that one ampoule can be live (at temperature and delivering precursor to a tool) while the other manifold can be in a standby, or offline state. A programmable logic controller controls the manifold valves and heat tracing and makes the tool “see” only one ampoule on the system by correctly setting the extra valves on the active manifold and redirecting the pneumatic valve signals from the tool to the appropriate valves on the active ampoule manifold. The programmable logic controller can control the cycle purging and ampoule swap steps on the inactive ampoule while the other one is in run. Since the tool only sees one ampoule, this is a plug and play solution for existing tools.

An advantage of the multiple ampoule delivery system of this invention is that semiconductor tool platforms are already designed for single ampoule precursor delivery systems. In the case where the precursor needs change (liquid to solid or thermally unstable liquid), the tool vendor does not have to redesign the platform to allow their tool to control multiple ampoules.

The cabinet the ampoules reside in optionally keeps the ampoules separated by a wall. Depending on safety requirements, one cabinet with a single door and no dividing wall may be suitable for use in this invention. Each ampoule can be accessed by its own door that can be interlocked with the programmable logic controller to prevent tampering with the online ampoule. The ampoules are mounted on shelves that allow the ampoule to be manipulated in and out of the cabinet and slightly up and down and about their own axis for alignment with the manifolding.

Advantages of a multiple ampoule system over a bulk fill system include, for example, over a single ampoule, the multiple ampoule system has zero tool downtime during ampoule change out; over a bulk fill, the multiple ampoule system allows a user to avoid potentially hazardous organometallic precursor liquid filled lines running through the fab; and bulk systems fill new precursor on top of used precursor, concentrating impurities in the ampoule while the dual ampoule system removes the used ampoule to replace it with a fresh one.

For precursors heated to high operating temperatures, a bulk fill system still requires cool-down of the ampoule to begin top off, while a dual ampoule system allows the new ampoule to be installed and brought to temperature while the other ampoule continues to supply precursor to the tool. In both cases, the tool may require a re-qualification run which would be dependent on the process owner and how repeatable they have determined the system and precursor supply to be. When the active ampoule is near empty, there is no waiting for refill or temperature stabilization before qualifying a second ampoule. Out of spec organometallic precursor in a bulk fill container would affect multiple ampoules on multiple tools. With the multiple ampoule system, the impact would be limited to one ampoule on one tool.

Other advantages are also apparent. Many bulk fill systems employ the use of a solvent to clean the liquid lines. The subsequent waste mixture of precursor and solvent adds to the cost of chemical disposal at the customer site. The dual ampoule system can be used easily for high melting point solid precursors such as metal chlorides that do not lend themselves to be transferred through lines as a liquid or solid. The dual ampoule system has a small manifold that is easy to replace if there is a particle or contamination problem and only affects one tool. A similar problem on a bulk-fill tank may require replacing multiple lengths of line, affecting multiple tools. Since the dual ampoule system uses the same single ampoules as a single ampoule system, this lends itself to lean (one piece flow) chemical inventory management.

Further, for large batch tools having multiple wafers, the multiple ampoule system of this invention can cut down time for a user for an ampoule swap typically from about 24 hours or greater to about 4 hours or less or about the time to qualify the new material. This can amount to a downtime reduction of greater than about 80 percent.

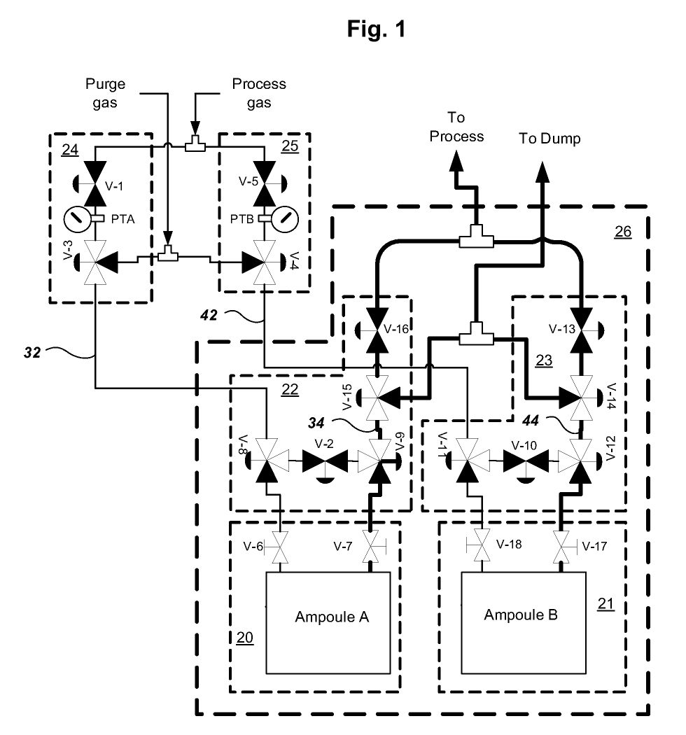

FIG. 1 depicts a valve schematic for a dual ampoule delivery system of this invention. With reference to FIG. 1, the dual ampoule delivery system includes two ampoules (20 and 21) hooked up to their own parallel gas manifolds (22 and 23) that can deliver organometallic precursor vapor to a common process tool. The gas fed to each manifold is chosen using purge/process manifolds 24 and 25 and when a given manifold is idle, it can be purged to the common dump line. The ampoules and manifolds are contained in a vented cabinet 26 with separate doors and sections for each ampoule. The gas lines are monitored for flow or no flow situations using the pressure transducers (PTA and PTB) located in the purge/process manifolds. The ampoules and manifolds can be temperature controlled as well.

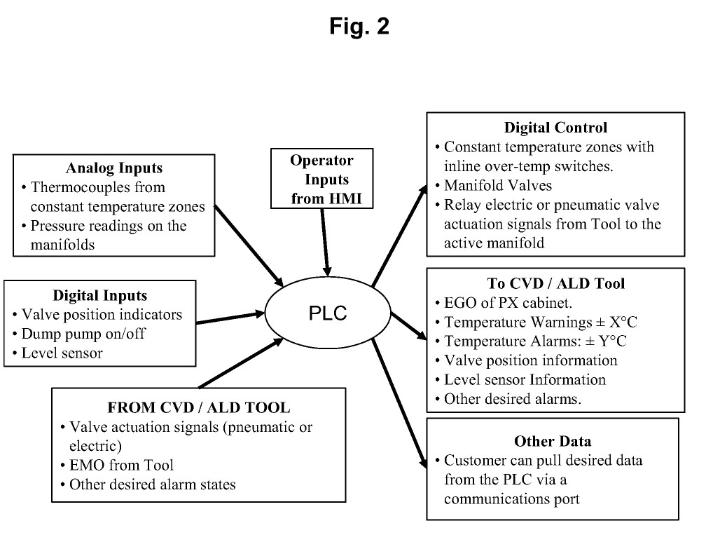

The operation of this dual ampoule delivery system is performed through a programmable logic controller. The typical inputs and outputs to and from the programmable logic controller that controls this dual ampoule system are shown in FIG. 2. The programmable logic controller takes various digital and analog inputs from the manifold and uses them to control temperature and perform operations. In addition, the programmable logic controller takes inputs from the process tool and directs those inputs to the active manifold. The programmable logic controller can also send out alarms as requested by the process tool and the end user. A human machine interface, such as a touchscreen, allows a user to configure the system and perform operations manually.

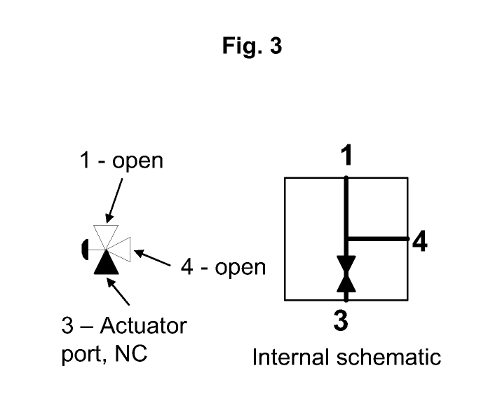

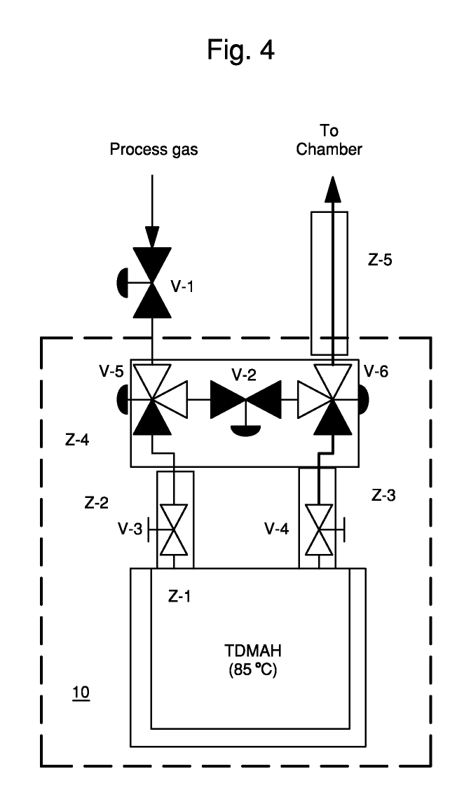

A preferred mode for practicing this invention is a dual ampoule delivery system controlled by a programmable logic controller. FIG. 3 describes the valve notation used herein. The standard single ampoule hook-up for a typical atomic layer deposition or chemical vapor deposition process tool is shown in FIG. 4. In this set-up, the ampoule and manifold above the ampoule are heated. In practice, the manifold above the ampoule (Z-4 and Z-5) is held at greater than 5° C. higher than the temperature set-point of the ampoule (Z-1, Z-2 and Z-3) to prevent precursor condensation in the lines. Valves V-3 and V-4 are manual valves that stay with the ampoule.

All valves in the FIG. 4 schematic are normally closed valves. Valves V-5 and V-6 are 3-port pneumatically actuated valves that allow the process tool to isolate the ampoule from the manifold. During precursor delivery, V-2 stays closed while the other valves are opened allowing a dry, inert carrier gas, such as argon or helium to pass into the ampoule and assist in the delivery of organometallic precursor, e.g., TDMAH, out of the ampoule to the process chamber. Typically, for atomic layer deposition applications, there is a final valve (not shown) down stream of V-6 located as close to the chamber as possible as a final isolation point. This final valve is integrated into the tool.

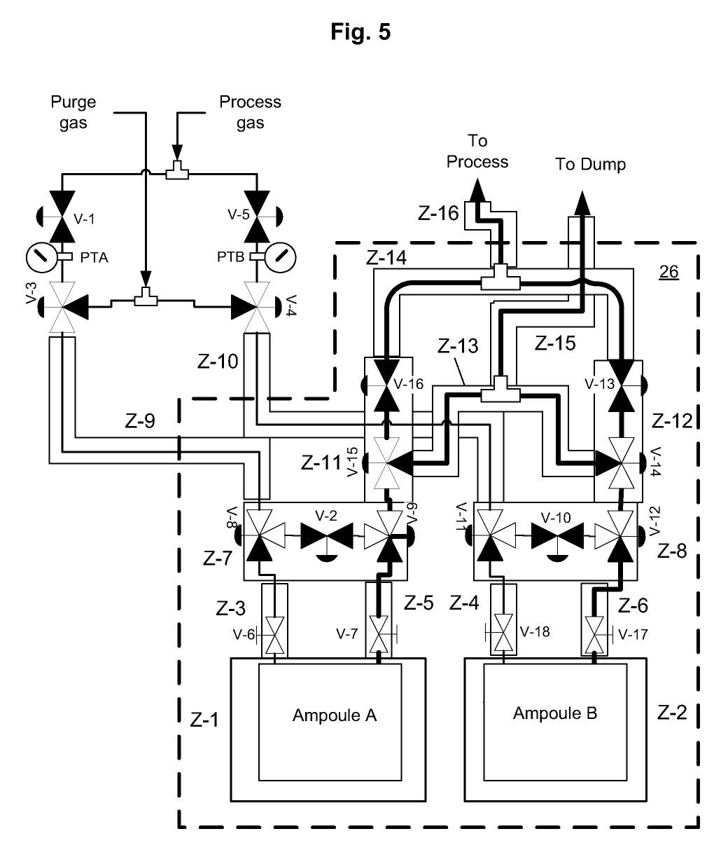

The preferred piping and instrumentation for the dual ampoule delivery system is shown in FIG. 5. FIG. 5 shows valves, pressure transducers and hot zones. A common practice in the gas delivery industry is to use pressure transducers in both the upstream and the downstream positions. As seen in FIG. 5, this system only has pressure transducers (PTA and PTB) upstream of the ampoules. Pressure transducers downstream of the organometallic precursor would act as dead legs, heat sinks and another connection point for leaks. These could all lead to particulate formation in the manifold. In addition, all of the information needed to determine if a valve is not opening or there is a leak in the line can be obtained with one pressure transducer per manifold.

In FIG. 5, the valves analogous to those controlled by the CVD tool in the standard ampoule hook-up are V-1, V-2, V-8 and V-9 for ampoule A and V-5, V-10, V-11 and V-12 for ampoule B.

The inputs and outputs that the programmable logic controller is responsible for are shown schematically in FIG. 2. The programmable logic controller is designed to take in various analog and digital signals from the manifold along with commands from the tool or operator via the operator machine interface (HMI). With reference to FIG. 5, the programmable logic controller controls all 16 temperature zones and the 14 manifold valves and monitors the respective thermocouples and valve position indicators for feedback. The programmable logic controller relays pneumatic or electric valve open commands from the tool to the active manifold and will shut down to a safe state if the tool is shut down in an emergency (EMO—emergency off).

The programmable logic controller has an algorithm for directing communication with each of the sourcing gas manifolds, each of the carrier gas feed/vapor phase reagent delivery manifolds, each of the vessels, and the deposition chamber, in such a way that each of the sourcing gas manifolds are operable independently of one another, each of the carrier gas feed/vapor phase reagent delivery manifolds are operable independently of one another, and each of the vessels are operable independently of one another.

The programmable logic controller can receive digital and analog inputs from each of the sourcing gas manifolds, each of the carrier gas feed/vapor phase reagent delivery manifolds, and each of the vessels, and uses the digital and analog inputs to perform operations. The controller can also receive command inputs from the deposition chamber, and uses the command inputs to perform operations.

The digital and analog inputs from each of the carrier gas feed/vapor phase reagent delivery manifolds, each of the vessels, and each of the sourcing gas manifolds comprise analog inputs involving thermocouples from constant temperature zones and pressure readings on each of the carrier gas feed/vapor phase reagent delivery manifolds and each of the sourcing gas manifolds, and digital inputs involving valve position indicators, dump pump on/off, and level sensors on each of the vessels. The command inputs from the deposition chamber comprise pneumatic and electric valve actuation signals, emergency off (EMO) from said deposition chamber, and alarm states.

With respect to the digital and analog inputs received above, the operations performed can include controlling temperature in separate temperature zones in each of said carrier gas feed/vapor phase reagent delivery manifolds, each of said vessels, and each of said sourcing gas manifolds; controlling valves in each of said carrier gas feed/vapor phase reagent delivery manifolds and each of said sourcing gas manifolds; monitoring thermocouples and valve position indicators for feedback in each of said carrier gas feed/vapor phase reagent delivery manifolds, each of said vessels, and each of said sourcing gas manifolds; relaying electric and pneumatic valve actuation signals from the deposition chamber to each of said active carrier gas feed/vapor phase reagent delivery manifolds and each of said active sourcing gas manifolds; and communicating with said deposition chamber involving emergency gas off (EGO) of cabinet, temperature warnings, temperature alarms, valve position information, level sensor information and other alarms.

With respect to the command inputs received above, the operations performed can include controlling temperature in separate temperature zones in each of said carrier gas feed/vapor phase reagent delivery manifolds, each of said sourcing gas manifolds, and each of said vessels; controlling valves in each of said carrier gas feed/vapor phase reagent delivery manifolds and each of said sourcing gas manifolds; monitoring thermocouples and valve position indicators for feedback in each of said carrier gas feed/vapor phase reagent delivery manifolds, each of said vessels, and each of said sourcing gas manifolds; relaying electric and pneumatic valve actuation signals from the deposition chamber to each of said active carrier gas feed/vapor phase reagent delivery manifolds and each of said active sourcing gas manifolds; and communicating with said deposition chamber involving emergency gas off (EGO) of cabinet, temperature warnings, temperature alarms, valve position information, level sensor information and other alarms.

The operations performed from receiving the digital and analog inputs above can include controlling temperature states and valve states separately in each of the carrier gas feed/vapor phase reagent delivery manifolds, each of the sourcing gas manifolds, and each of the vessels. The temperature states and valve states comprise offline, manual, ampoule change, and process. The process comprises standby, push button or call for gas, and online.

The operations performed from receiving the command inputs above can include controlling temperature states and valve states separately in each of the carrier gas feed/vapor phase reagent delivery manifolds, each of the sourcing gas manifolds, and each of the vessels. The temperature states and valve states comprise offline, manual, ampoule change, and process. The process comprises standby, push button or call for gas, and online.

In an embodiment, the controller relays the digital and analog inputs to a computer, allowing a user to monitor said operations, and relays the command inputs to a computer, allowing a user to monitor said operations.

Each of the vessels can include at least one source chemical level sensor and at least one temperature sensor. The programmable logic controller can direct communication with each of the source chemical level sensors and each of the temperature sensors to operate each of the sourcing gas manifolds independently of one another, each of the carrier gas feed/vapor phase reagent delivery manifolds independently of one another, and each of the vessels independently of any other of said vessels.

The programmable logic controller can also take a desired action in the case where there is a no-flow or heater failure on the tool end. The programmable logic controller can monitor a signal from the dump pump to be sure it is on before opening a manifold to dump and can monitor a level sensor on each ampoule to alert the tool of a low precursor state. In addition, the programmable logic controller can alert the tool to an out of temperature event in one of the zones or an emergency shut-down. It will also relay the appropriate valve position indicators from the active valves over to the tool if that is required. All the data that the programmable logic controller receives can be re-broadcast via Ethernet connection, allowing the end user to monitor temperatures, pressures, and the like, for SPC or developmental purposes.

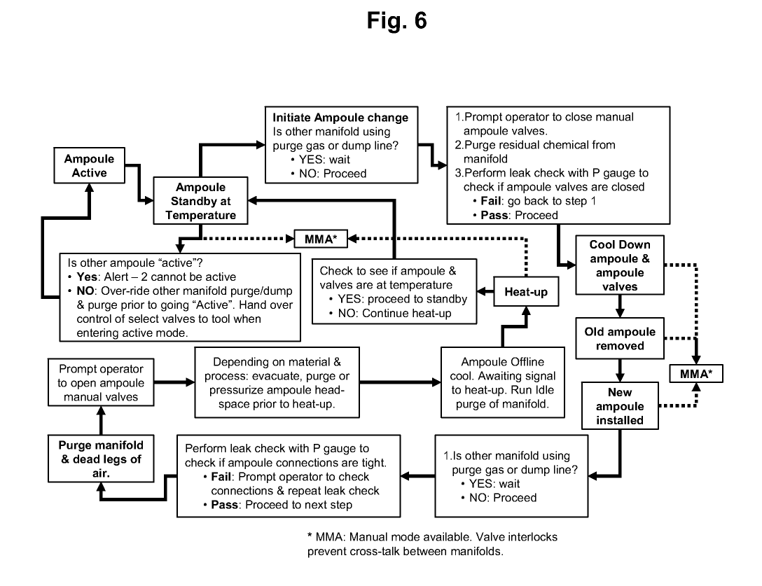

Another unique aspect of the integrated vapor or liquid phase reagent dispensing apparatus is that the programmable logic controller (PLC) controls both the temperature and valve states of two separate manifolds feeding a common process tool. A flow-sheet showing the general flow and decisions required by the PLC is shown in FIG. 6. Throughout all steps, the PLC is monitoring inputs such as line pressures, temperatures, valve states, and the like, to ensure that the system is within its specified operating limits. In addition, the PLC is programmed such that certain valves cannot open at the same time, preventing “cross-talk” between the manifolds. For example, both outlet to process valves or outlet to dump valves cannot be open at the same time. In an embodiment, the temperature of each of the carrier gas feed/vapor phase reagent delivery manifolds and each of the sourcing gas manifolds is at least 5° C. or greater than the temperature of each of the vessels.

Starting at the top left of the FIG. 6 schematic diagram, an ampoule can be in the “Ampoule Active” state. In this state, it is at temperature and the PLC is monitoring the temperatures of the active ampoule and its respective manifolds. It is also diverting signals from the tool to the appropriate active manifold. It is in this active state that the tool can run process from the ampoule.

From the “Ampoule Active” state, the ampoule and its respective manifold can be put into a “Standby” state. In this state, the ampoule is at temperature and ready to be taken offline or put into an active state. During this “standby” state, the tool does not have control of any valves on the respective manifold. From “Ampoule Standby at Temperature”, an operator can go back to Active, into a manual mode, or begin ampoule swap back.

To go back into “Active” from Standby, the controller purges the manifold for a user specified amount of time and then hands over control of the appropriate valves on that manifold to the tool.

In going to “Initiate an Ampoule Change”, the PLC checks to be sure the other manifold is not using the purge gas or dump line then will prompt the operator to close the ampoule manual valves so that a manifold purge can be performed. This purge is done to eliminate residual organometallic from the manifold and the legs of tubing between the ampoule valve and the manifold valves so that when the ampoule is removed, no residual precursor in those legs will react with the air or moisture in the air.

After cycle purging the manifold, the PLC checks to be sure the ampoule valves are closed. This is done via a leak-up where the manifold is pumped to base pressure, isolated and then the pressure rise is observed. If the ampoule is closed and residual chemical has been purged from the line, the manifold will not exhibit a significant pressure rise. If the leak check is failed, the operator is prompted to investigate.

After a successful leak check, the controller will shut down the heaters and prompt an operator to change out the ampoule when it reaches a safe temperature.

Once the new ampoule is installed and the operator acknowledges it, the PLC will perform another leak check to ensure that the ampoule has been hooked up correctly and then begin purging the manifold to eliminate residual air and moisture that may have adsorbed during ampoule hook-up. The PLC will walk the operator through opening the ampoule valves and then may evacuate, purge or pressurize the ampoule head-space prior to heat-up. This is user dependent. The ampoule will then wait for a signal to heat-up either from an operator through the human machine interface (HMI) or from the tool, in the case of a more integrated system.

Once the ampoule, its valves and the manifold have stabilized at the setpoint temperature, the ampoule will enter the “Ampoule Standby at Temperature” state, ready to go “Active” when needed.

The PLC can also include a password protected Manual mode that will allow a skilled technician or engineer to manually actuate valves for purposes of helium leak checking, manifold replacement, system checks, and the like. As an added safety measure, valve exclusion is programmed into the programmable logic controller to prevent cross-talk between the active manifold and the inactive manifold. The ampoules could be designed exclusively with automatic valves, however, that is not standard practice since manual valves allow an operator to ensure a tight seal.

The PLC determines which manifold is active. This can be initiated by: 1) a manual button where the tool operator knows the run limit of an ampoule has been reached and commands the switch-over; or 2) an auto-switchover function that uses data from the level sensors or counter from the tool to determine when one ampoule is low and that the other ampoule should be brought online. Another case is where the PLC alerts the operator that switchover will be needed but waits for operator input to execute.

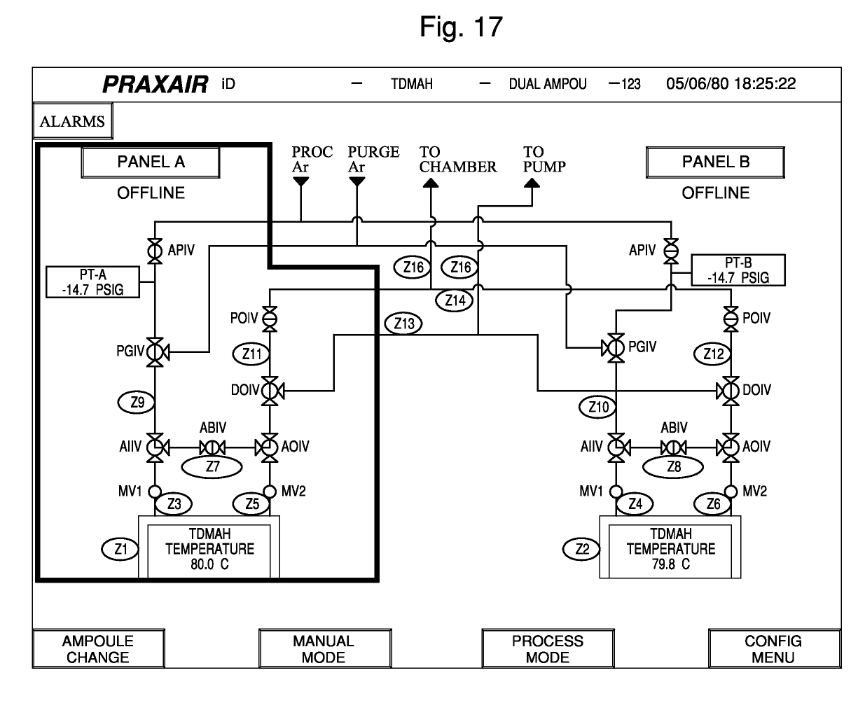

An illustrative screen shot of a PLC screen used in an integrated vapor or liquid phase reagent dispensing apparatus is shown is FIG. 17.

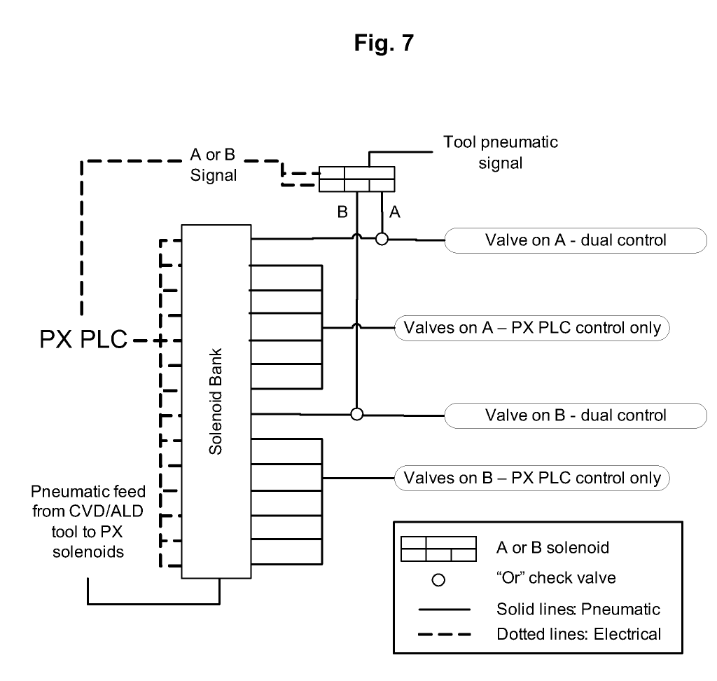

One of the unique aspects of the integrated vapor or liquid phase reagent dispensing apparatus is the design of a safe way for the programmable logic controller to redirect valve-open pneumatic signals from the process tool to the appropriate active manifold while still allowing the programmable logic controller to control those valves when the manifold was in an inactive state. In addition, for safety purposes, it is desired that when the pneumatics on the tool are locked out, the integrated vapor or liquid phase reagent dispensing apparatus valves would also be locked out. An example of this solution is shown schematically in FIG. 7.

To control common pneumatic valves, the programmable logic controller supplies a 24 Volt DC signal to a bank of solenoid valves hooked to a common main pneumatic feed. In this case, the main pneumatic line that supplies the cabinet is being drawn from the tool. This means if the tool pneumatics are locked out, so are the integrated vapor or liquid phase reagent dispensing apparatus pneumatics. Additionally, for dual control of the common valves, each pneumatic signal from the tool is directed to a special solenoid (or equivalent) that can be energized to send the pneumatic signal to the appropriate valve on either manifold of the integrated vapor or liquid phase reagent dispensing apparatus. The “OR” check valve (e.g., a 3 ported shuttle valve) allows pneumatic signal to those shared valves to come from either the main solenoid panel or the stand-alone A or B solenoid, e.g., 4 position 3-port valve, without bleeding off of the others exhaust.

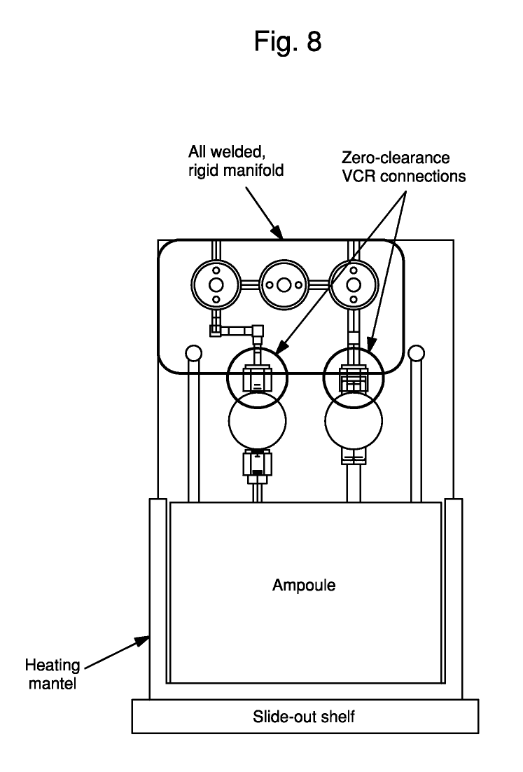

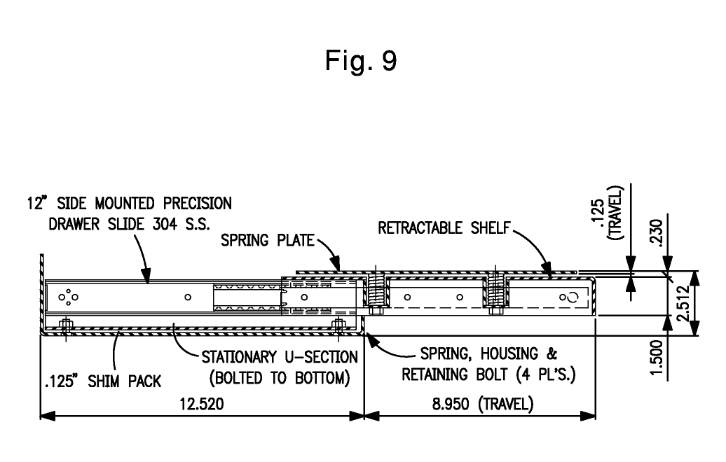

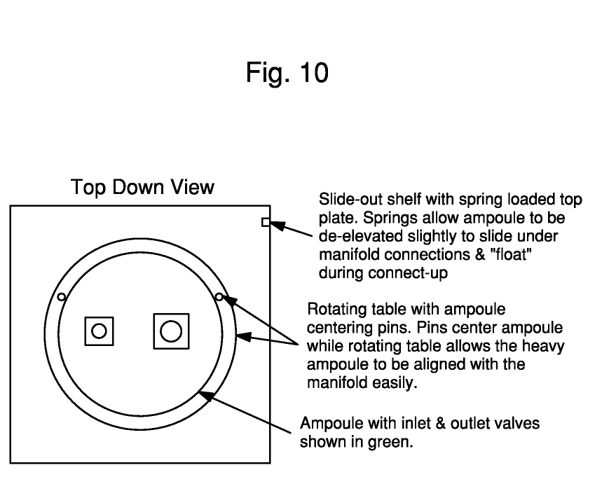

The ampoule can be located inside of a small vented cabinet. The ampoule typically rests on a shelf and the manifold above it is, by nature of its design, a fairly rigid structure. A typical ampoule mounting is shown in FIG. 8. The ampoule can sit inside of a semi-flexible heating mantle on top of a fixed or sliding (in and out of the page) shelf. The use of high vacuum VCR connections also result in a zero-clearance fit between the ampoule valves and the manifold. An embodiment is to use the play in the heating mantel to account for variation in the ampoule height. This makes building and hitting tolerances in the cabinet difficult. If the shelf is too high, the ampoule will not fit under the manifold. If the shelf is too low, the connections may not be tightened correctly or the entire weight of the ampoule (35-40 lbs) may wind up being supported by the manifold, stressing the welds and fittings. For ease of loading the ampoule, a sliding shelf with an integrated spring-loaded plate can be used as shown in FIG. 9. The shelf can incorporate centering pins and a rotating table as shown in FIG. 10. All of these features can enable an operator to center the ampoule, align the connections and slide it under the rigid manifold with ease.

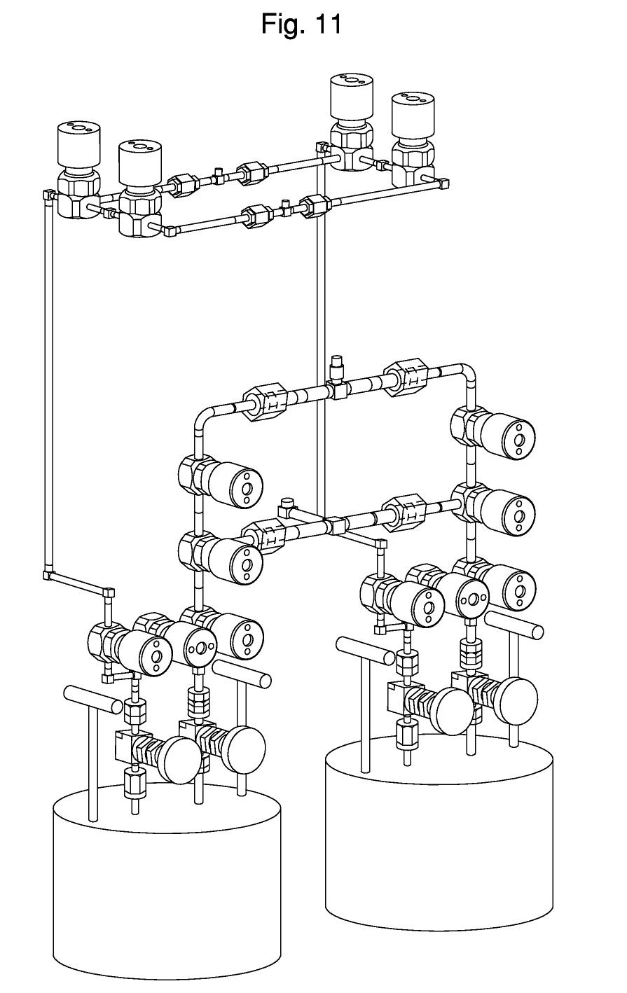

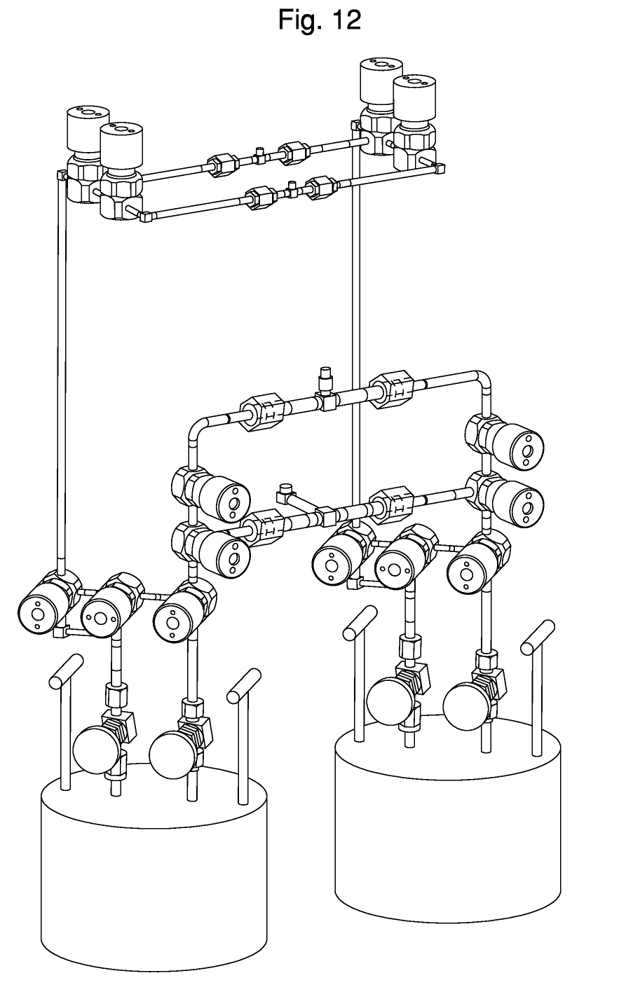

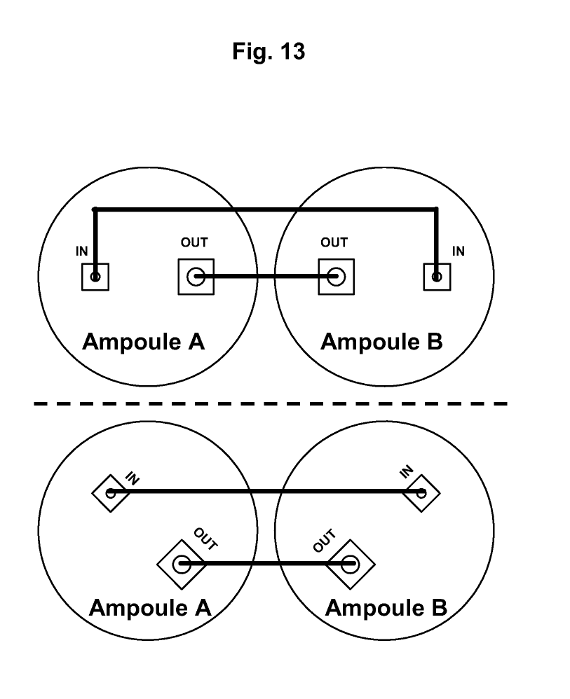

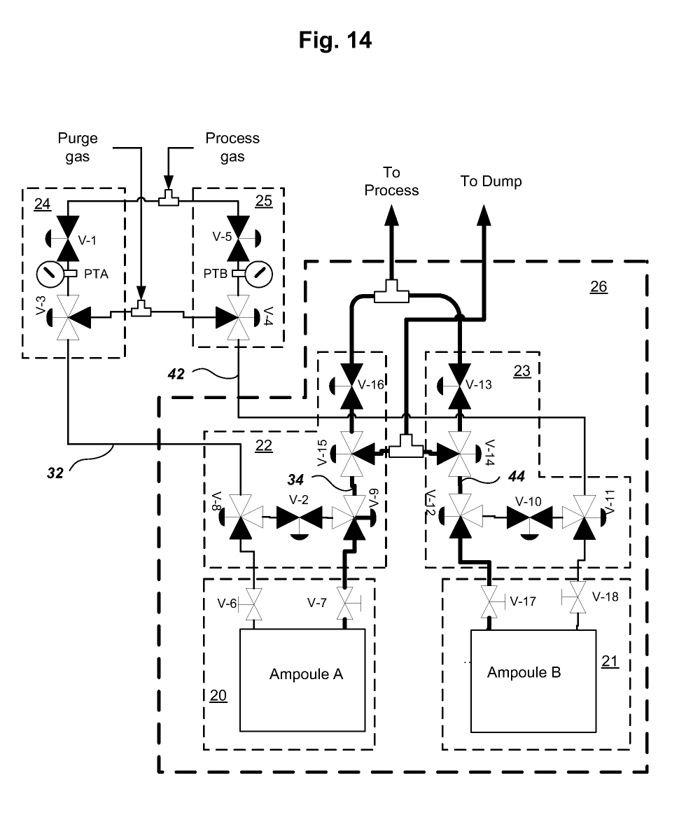

The layout of the ampoules can affect the number of bends and line lengths in the manifolds above. In practice, it is best to minimize “dead legs” and unnecessary bends on the precursor delivery line. This is done to minimize the opportunity for condensation, particulates and enable the thorough removal of residual precursor during purging. For example, one embodiment with identical ampoules facing forward is shown in FIG. 11 while another embodiment in FIG. 12 shows how rotating the ampoules clockwise, about their center axis by 45 degrees, can eliminate two bends in the inlet argon legs and reduce the length of the common outlet line between manifolds. One could also visualize the case of side specific ampoules where one ampoule (A) has the inlet on the left and the other ampoule (B) has the inlet on is right. In this case, ampoule (A) could be rotated clockwise about its vertical axis and ampoule (B) counterclockwise about its vertical axis resulting in a very short outlet to outlet distance for the common manifold tee as shown in FIG. 13. The schematic showing the layout of the side specific ampoule case is shown in FIG. 14. As shown in FIG. 14, the ampoule inlets V-6 and V-18 are on opposite sides and the outlet valves (V-7 and V-17) are towards the center. This orientation allows the length of line connecting the two ampoules to the common manifold to be minimized, important for reducing dead-leg volume.

At times, the vessels near empty of the product liquid precursor. The near-empty status can be detected by a liquid level sensor. Conventional level sensor can be useful that are consistent with the teachings herein. The sensors may indicate, for example, that a vessel may need to be changed out or refilled, but it does not need to be done immediately.

If necessary, the tool's process may be completed, with a small precursor supply remaining in the vessel. The sensors may also indicate that the tool's process must be stopped because the vessel does not contain an adequate precursor supply. The sensors may also indicate that the vessel is full.

When it is time to refill and/or replace a vessel, a change-over procedure occurs wherein the vessel is removed from the integrated vapor or liquid phase reagent dispensing apparatus. Opening the system to ambient conditions exposes reactive precursor remnants in the system to atmospheric components, most notably oxygen and moisture. Therefore, the remnants must be purged from the lines before opening the system. Most purging can be accomplished using gases and/or a vacuum. For those precursor remnants not removed by these methods, a solvent can be used to sufficiently flush the lines. Certain parts of the integrated vapor or liquid phase reagent dispensing apparatus exposed to the reactive precursor can be flushed with an appropriate solvent which is purged through an exit line leading to a dump. The solvent flush can be supported by the solvent tank and manifold. Alternatively, a purge gas is inserted into the integrated vapor or liquid phase reagent dispensing apparatus through a valve and the waste travels to the dump through a vent line. A residual pressure during these evacuation processes can be monitored by a pressure sensor.

The various parts and operations of the integrated vapor or liquid phase reagent dispensing apparatus are controlled by a controller. The controller is configured to control each vessel-manifold combination independently of the other vessel-manifold combinations. Thus, precursor in one vessel is managed and distributed independently of precursor in other vessels, and the entire process of providing the precursors to a manufacturing tool is flexible. For example, one precursor may be supplied at a time, or multiple precursors at a time. Further, one or more vessels may be changed out while other vessels are supplying precursor material.

The connecting lines in and between the vessels, manifolds and various others parts of the integrated vapor or liquid phase reagent dispensing apparatus are designed to retain the chemicals described herein. For example, the lines may be made of high purity stainless steel tubing. The shut-off valves described herein may be spring-less diaphragm high purity valves.

In operation, the integrated vapor or liquid phase reagent dispensing apparatus is controlled by a controller having an algorithm, the controller directing communication between the several units and completing the integrated system. The several units of the system communicate through various shared components. The controller and the different units, in any combination, having their shared components allow the integrated system to perform as a modular tool. The controller may be any of various controllers consistent with the teachings herein, and may be located in various places. The controller is adaptable to communicate with the various systems of the integrated vapor or liquid phase reagent dispensing apparatus in such a way that the vessels are operable independently of one another. Alternatively, if separate controllers are used in the tool and the integrated vapor or liquid phase reagent dispensing apparatus, the controllers communicate with each other so that the tool knows when chemicals tanks are being exchanged and the integrated vapor or liquid phase reagent dispensing apparatus knows when the tool requires precursors.

The remaining amounts of precursors in the vessels are also monitored by the controller algorithm. The vessels may be monitored continuously or discretely. The vessels may include, for example, external sensors such as weight scales and ultrasound sensors. The vessels may also include, for example, internal sensors such as those previously mentioned. When a vessel sensor signals a low level the tank exchange procedure is initiated as described herein.

The embodiments of the integrated vapor or liquid phase reagent dispensing apparatus described herein provide a modular, integrated processor for continuously supplying precursors to a target process tool. The integrated vapor or liquid phase reagent dispensing apparatus may also be combined with other modules to provide a system for storing and delivering the precursors to a tool, such that the manufacturing tool can successfully and continuously receive precursors for deposition.

The above discussion is meant to be illustrative of the principles and various embodiments of this invention. While embodiments of this invention have been shown, modifications thereof can be made by one skilled in the art without departing from the teachings of the invention. The embodiments described herein are exemplary only, and are not limiting. Many variations and modifications of the invention and apparatus and methods disclosed herein are possible and are within the scope of the invention. Accordingly, the scope of protection is not limited by the description set out above, but is only limited by the claims which follow, that scope including all equivalents of the subject matter of the claims.

It is understood that various combinations of vessels, manifolds, pressure regulators, valves and orifices may be used with the embodiments of this invention. This invention should not be limited to the combinations of such devices described herein and persons of ordinary skill in the art will appreciate that this invention includes other combinations consistent with the teachings herein.

Referring to FIGS. 1, 5, 14 and 16, process gas is the carrier gas. That is the gas that will be entering the ampoule or mixing with the precursor to dilute it during delivery to the “process”. The purge gas is only used to purge out the manifold after the ampoule is spent or during new ampoule hook up. For example, a customer may want to use electronic grade argon as the carrier gas, but stick to electronic grade nitrogen for the purge gas because it is cheaper.

Referring to FIGS. 1, 5 and 14, the vessels (e.g., 20 and 21) can comprise a portion of the top wall member having a carrier gas feed inlet opening through which carrier gas can be fed into said inner gas volume above the fill level to cause vapor of said source chemical to become entrained in said carrier gas to produce vapor phase reagent; and a portion of the top wall member having a vapor phase reagent outlet opening through which said vapor phase reagent can be dispensed from said apparatus.

The vessels (e.g., 20 and 21) can comprise a carrier gas feed line (e.g., 32 and 42 in FIG. 14) extending from the carrier gas feed inlet opening upwardly and exteriorly from the top wall member for delivery of carrier gas into said inner gas volume above the fill level, the carrier gas feed line (e.g., 32 and 42 in FIG. 14) containing carrier gas flow control valves (e.g., V-1, V-3, V-6 and V-8 for ampoule 20; and V-4, V-5, V-11 and V-18 for ampoule 21) and pressure transducer (e.g., PTA and PTB) therein for monitoring and controlling the pressure of the sourcing gas manifold; and a vapor phase reagent discharge line (e.g., 34 and 44 in FIG. 14) extending from the vapor phase reagent outlet opening upwardly and exteriorly from the top wall member for removal of vapor phase reagent from said inner gas volume above the fill level, the vapor phase reagent discharge line (e.g., 34 and 44 in FIG. 14) containing vapor phase reagent flow control valves (e.g., V-7, V-9, V-15 and V-16 for ampoule 20; and V-12, V-13, V-14 and V-17 for ampoule 21) therein for control of flow of the vapor phase reagent therethrough.

In an embodiment, the vessels (e.g., 20 and 21) can comprise a portion of the top wall member having a carrier gas feed inlet opening comprising a bubbler tube that extends through the inner gas volume into the source chemical and through which said carrier gas can be bubbled into the source chemical to cause at least a portion of source chemical vapor to become entrained in said carrier gas to produce a flow of vapor phase reagent to said inner gas volume above the fill level, said bubbler tube having an inlet end adjacent to the top wall member and an outlet end adjacent to the bottom wall member; and a portion of the top wall member having a vapor phase reagent outlet opening through which said vapor phase reagent can be dispensed from said apparatus.

The vessels having a bubbler tube can comprise a carrier gas feed line (e.g., 32 and 42 in FIG. 14) extending from the carrier gas feed inlet opening upwardly and exteriorly from the top wall member for delivery of carrier gas into said source chemical, the carrier gas feed line (e.g., 32 and 42 in FIG. 14) containing carrier gas flow control valves (e.g., V-1, V-3, V-6 and V-8 for ampoule 20; and V-4, V-5, V-11 and V-18 for ampoule 21) and pressure transducer (e.g., PTA and PTB) therein for monitoring and controlling the pressure of the sourcing gas manifold; and a vapor phase reagent discharge line (e.g., 34 and 44 in FIG. 14) extending from the vapor phase reagent outlet opening upwardly and exteriorly from the top wall member for removal of vapor phase reagent from said inner gas volume above the fill level, the vapor phase reagent discharge line (e.g., 34 and 44 in FIG. 14) containing vapor phase reagent flow control valves (e.g., V-7, V-9, V-15 and V-16 for ampoule 20; and V-12, V-13, V-14 and V-17 for ampoule 21) therein for control of flow of the vapor phase reagent therethrough.

In another embodiment, the vessels (e.g., 20 and 21) can comprise a portion of the top wall member having an inert gas feed inlet opening through which said inert gas can be fed into the inner gas volume above the fill level to pressurize the inner gas volume above the fill level; and a portion of the top wall member having a liquid phase reagent outlet opening comprising a diptube that extends through the inner gas volume into the source chemical and through which liquid phase reagent can be dispensed from said apparatus, said diptube having an outlet end adjacent to the top wall member and an inlet end adjacent to the bottom wall member.

The vessels (e.g., 20 and 21) having a diptube can comprise an inert gas feed line (e.g., 32 and 42 in FIG. 14) extending from the inert gas feed inlet opening upwardly and exteriorly from the top wall member for delivery of inert gas into said inner gas volume above the fill level, the inert gas feed line (e.g., 32 and 42 in FIG. 14) containing inert gas flow control valves (e.g., V-1, V-3, V-6 and V-8 for ampoule 20; and V-4, V-5, V-11 and V-18 for ampoule 21) and pressure transducers (e.g., PTA and PTB) therein for monitoring and controlling the pressure of the sourcing gas manifold; and a liquid phase reagent discharge line (e.g., 34 and 44 in FIG. 14) extending from the liquid phase reagent outlet opening upwardly and exteriorly from the top wall member for removal of liquid phase reagent from said vessel, the liquid phase reagent discharge line (e.g., 34 and 44 in FIG. 14) containing liquid phase reagent flow control valves (e.g., V-7, V-9, V-15 and V-16 for ampoule 20; and V-12, V-13, V-14 and V-17 for ampoule 21) therein for control of flow of the liquid phase reagent therethrough.

The vessels or ampoules are typically machined from stainless steel, e.g., 316L, and electropolished to prevent contamination of the precursor liquid or solid source chemical. The cover or top wall member can be non-removable or removable to facilitate cleaning and reuse. The vessel can comprise a cylindrically shaped side wall member or side wall members defining a non-cylindrical shape. Vessels with removable top wall members can include fastening means for securing the top wall member to the sidewall member. Illustrative fastening means include, for example, welded members, bolts or seals.

The ampoules can include inlet and outlet valves, e.g., on/off valves and mass control valves, to allow the chemicals to be delivered to the end use equipment. Optional ampoule equipment include a fill port and a source chemical level sensor to determine when the ampoule is nearly empty. The material in the container is delivered either under vacuum, for low vapor pressure chemicals, or using an inert gas to sweep the vapors out. The material may alternatively be delivered as a liquid through a dip tube to the end use equipment where it can be vaporized or dispensed as needed.

A temperature sensor is preferably included in the ampoules to ensure uniform heat conduction. A source chemical level sensor is preferably included in the ampoules to ensure efficient use of the source chemical. The valves and source chemical level sensor are attached via face seal connections to ensure a clean, leak proof seal. Once assembled in a clean room, the ampoule is conditioned to remove adsorbed water and leak checked with a helium leak detector. The ampoules are designed to be used at pressures from a few torr to slightly above ambient.

In an embodiment of this invention, the temperature sensor extends from an upper end exterior of the vessel through a portion of the top wall member and generally vertically downwardly into the interior volume of the vessel, with the lower end of the temperature sensor being located in non-interfering proximity to the surface of the bottom wall. The source chemical level sensor extends from an upper end exterior of the vessel through a portion of the top wall member and generally vertically downwardly into the interior volume of the vessel, with the lower end of the source chemical level sensor being located in non-interfering proximity to the surface of the bottom wall. The temperature sensor is operatively arranged in the vessel to determine the temperature of source chemical in the vessel, the source chemical level sensor is operatively arranged in the vessel to determine the level of source chemical in the vessel, the temperature sensor and source chemical level sensor are located in non-interfering proximity to each other in the vessel, with the lower end of the temperature sensor being located at the same or closer proximity to the surface of the vessel in relation to the lower end of the source chemical level sensor, and the temperature sensor and source chemical level sensor are in source chemical flow communication in the vessel. The source chemical level sensor is selected from ultrasonic sensors, optical sensors, capacitive sensors and float-type sensors, and said temperature sensor comprises a thermowell and thermocouple.

In an embodiment of this invention, the bottom wall member optionally provides a sump cavity in which the lower end of a temperature sensor, source chemical level sensor, dip tube and/or bubbler tube may be disposed. Such a configuration can permit a high percentage, e.g., 95% or greater, preferably 98% or greater, of the volume of the originally furnished liquid or solid source chemical to be utilized in the application for which the source chemical is selectively dispensed. This configuration can also improve the economics of the source chemical supply and dispensing system and processes in which the dispensed source chemical is employed.

This invention allows for a minimal amount of semiconductor precursor chemical to remain in the ampoules or bubblers when the source chemical level sensor has signaled the end of the contents. This is very important as the complexity and cost of semiconductor precursors rises. In order to minimize costs, semiconductor manufacturers will want to waste as little precursor as possible. In addition, this invention places the temperature sensor in the same recessed sump cavity as the source chemical level sensor. This ensures that the true temperature of the source chemical semiconductor precursor will be read as long as the source chemical level sensor indicates there is precursor present. This is important from a safety standpoint. If the temperature sensor was to be outside of the semiconductor precursor it would send a false low temperature signal to the heating apparatus. This could lead to the application of excessive heat to the ampoule which can cause an unsafe situation and decomposition of the semiconductor precursor.

Referring again to the vessels or ampoules, the vessels can be equipped with a source chemical level sensor which extends from an upper portion exterior of the vessel, downwardly through a non-centrally located portion of the top wall member of the vessel, to a lower end, non-centrally located on the bottom floor member, optionally in close proximity to the surface of the sump cavity of the vessel to permit utilization of at least 95% of source chemical reagent when source chemical reagent is contained in the vessel. The upper portion of the source chemical level sensor may be connected by a source chemical level sensing signal transmission line to a central processing unit, for transmission of sensed source chemical level signals from the source chemical level sensor to the central processing unit during operation of the system.

In a like manner, the vessels can be equipped with a temperature sensor, i.e., a thermowell and thermocouple, which extends from an upper portion exterior of the vessel, downwardly through a centrally located portion of the top wall member of the vessel, to a lower end, centrally located on the bottom wall member, in close proximity to the surface of the bottom wall of the vessel. The upper portion of the temperature sensor may be connected by a temperature sensing signal transmission line to a central processing unit, for transmission of sensed temperature signals from the temperature sensor to the controller or central processing unit during operation of the system.

The controller or central processing unit, which may comprise a suitable microprocessor, computer, or other appropriate control means, may also be joined by a control signal transmission line to flow control valves (e.g., via a suitable valve actuator element) to selectively adjust flow control valves (e.g., V-1, V-3, V-6 and V-8 for ampoule 20; and V-4, V-5, V-11 and V-18 for ampoule 21) and control the flow of carrier gas to the vessel. The central processing unit may also be joined by a control signal transmission line to other flow control valves (e.g., via a suitable valve actuator element) to selectively adjust the flow control valves (e.g., V-7, V-9, V-15 and V-16 for ampoule 20; and V-12, V-13, V-14 and V-17 for ampoule 21) and control the discharge of vapor or liquid phase reagent from the vessel. For purposes of this invention, flow control valves shall include isolation valves, metering valves and the like.

This invention allows the semiconductor manufacturer to use the maximum amount of precursor while wasting very little before change-out of the ampoule. This minimizes waste and maximizes the return on the investment in the semiconductor precursor and specific application.

A typical ampoule consists of a vessel or cylinder of about five to six inches in diameter and five to seven inches in height and is constructed of 316 stainless steel (316SS). The top wall member is about a half of an inch thick and is attached by eight to twelve bolts to the sidewall member or may be welded on. The ampoule may or may not have an eductor (or dip) tube installed. A fill port may also be included. One valve may be used as an inlet for an inert gas to sweep the product out of the outlet valve. The ampoule may also have a bubbler tube. The bubbler tube can be used to bubble an inert gas through the product to assist in delivering the material as a vapor.

Illustrative source chemicals useful in this invention can vary over a wide range and include, for example, liquid or solid precursors for metals of Group 2 (e.g., calcium, strontium, and barium), Group 3 (e.g., yttrium and lanthanum), Group 4 (e.g., titanium, zirconium and hafnium), Group 5 (e.g., vanadium, niobium and tantalum), Group 6 (e.g., chromium, molybdenum and tungsten), Group 7 (e.g., manganese), Groups 8, 9 and 10 (e.g., cobalt, nickel, ruthenium, rhodium, palladium and platinum), Group 11 (e.g., copper, silver and gold), Group 12 (e.g., zinc and cadmium), Group 13 (e.g., aluminum, gallium, indium, and thallium), Group 14 (e.g., silicon, germanium and lead), Group 15 (e.g., antimony and bismuth), Group 16 (e.g., tellurium and polonium), the Lanthanide series and the Actinide series of the Periodic Table. Preferred source chemicals useful in this invention include liquid or solid precursors for metals selected from ruthenium, hafnium, tantalum, molybdenum, platinum, gold, titanium, lead, palladium, zirconium, bismuth, strontium, barium, calcium, antimony, thallium, aluminum, and rhodium, or precursors for metalloids selected from silicon and germanium. Preferred organometallic precursor compounds include ruthenium-containing, hafnium-containing, tantalum-containing and/or molybdenum-containing organometallic precursor compounds.

The source chemicals can be added to a vessel while the vessel is removed from the system and replaced with a fresh vessel. The temperature of the source chemical added to the vessel is not critical and can vary over a wide range. The source chemical can be heated to a temperature sufficient to vaporize the source chemical to provide a vapor phase reagent at an adequate flow rate to the process. Every material has a slight vapor pressure at room temperature and will vaporize under vacuum. The addition of heat increases the vaporization rate such that it is sufficient to provide the amount of chemical required in a reasonable time.

Solid source chemicals that sublime and solid source chemicals that melt upon heating can be used in this invention. For example, solid source chemicals that sublime can be used in the vapor phase reagent dispensing apparatus shown in FIGS. 1, 5, 14 and 16. Solid source chemicals that melt upon heating can be used in the vapor or liquid phase reagent dispensing apparatus shown in FIGS. 1, 5, 14 and 16. Likewise, liquid source chemicals can be used in the vapor phase reagent dispensing apparatus shown in FIGS. 1, 5 and 14. When using solid source chemicals that sublime, it may be necessary to employ dust entrapment equipment.

Illustrative vapor or liquid phase reagents useful in this invention can vary over a wide range and include, for example, vapor or liquid phase precursors for metals of Group 2 (e.g., calcium, strontium, and barium), Group 3 (e.g., yttrium and lanthanum), Group 4 (e.g., titanium, zirconium and hafnium), Group 5 (e.g., vanadium, niobium and tantalum), Group 6 (e.g., chromium, molybdenum and tungsten), Group 7 (e.g., manganese), Groups 8, 9 and 10 (e.g., cobalt, nickel, ruthenium, rhodium, palladium and platinum), Group 11 (e.g., copper, silver and gold), Group 12 (e.g., zinc and cadmium), Group 13 (e.g., aluminum, gallium, indium, and thallium), Group 14 (e.g., silicon, germanium and lead), Group 15 (e.g., antimony and bismuth), Group 16 (e.g., tellurium and polonium), the Lanthanide series and the Actinide series of the Periodic Table. Preferred vapor or liquid phase reagents useful in this invention include vapor or liquid phase precursors for metals selected from ruthenium, hafnium, tantalum, molybdenum, platinum, gold, titanium, lead, palladium, zirconium, bismuth, strontium, barium, calcium, antimony, aluminum, and rhodium, or precursors for a metalloids selected from silicon and germanium. Preferred organometallic precursor compounds include ruthenium-containing, hafnium-containing, tantalum-containing and/or molybdenum-containing organometallic precursor compounds.

The deposition chamber can be a chemical vapor deposition chamber or an atomic layer deposition chamber. The vapor phase reagent discharge line (e.g., 34 and 44 in FIG. 14) connects the vessel to the deposition chamber. A heatable susceptor or substrate (e.g., wafers may be held vertically on a quartz boat in a vertical furnace tube with heaters on the outside radiatively heating the wafers) is contained within the deposition chamber and is located in a receiving relationship to the vapor phase reagent discharge line (e.g., 34 and 44 in FIG. 14). An effluent discharge line is connected to the deposition chamber. The vapor phase reagent passes through the vapor phase reagent discharge line (e.g., 34 and 44 in FIG. 14) and into the deposition chamber, for contact with a substrate, optionally on the heatable susceptor, and any remaining effluent is discharged through the effluent discharge line. The effluent may be passed to recycle, recovery, waste treatment, disposal, or other disposition means.

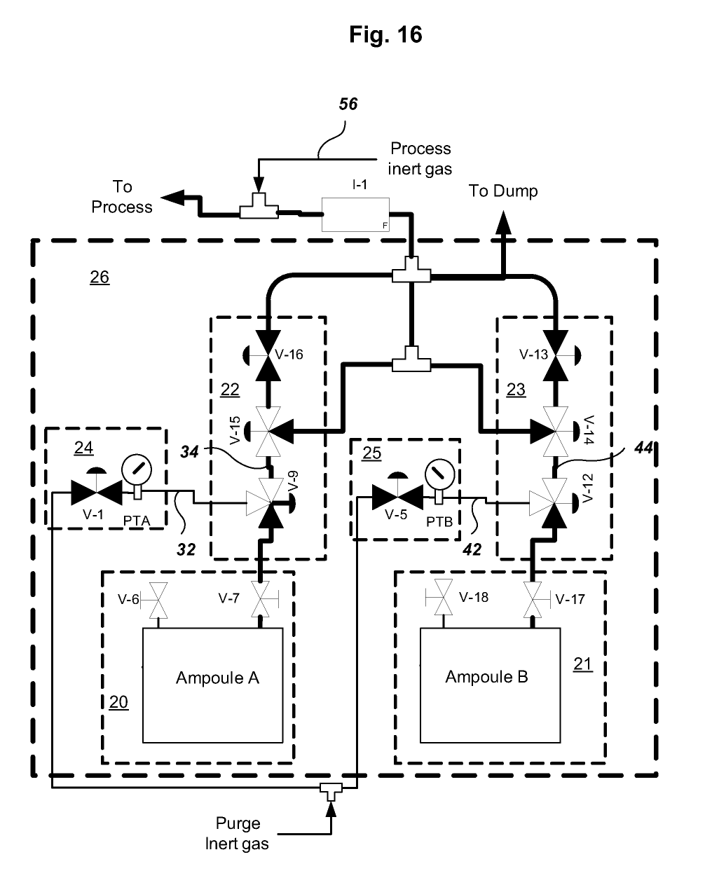

Referring to FIG. 16, this invention relates in part to an integrated vapor phase reagent dispensing apparatus comprising:

a plurality of vessels (e.g., 20 and 21), each vessel comprising a top wall member, a sidewall member and a bottom wall member configured to form an internal vessel compartment to hold a source chemical; and a portion of the top wall member having a vapor phase reagent outlet opening through which said vapor phase reagent can be dispensed from said vessel;

a plurality of vapor phase reagent delivery manifolds (e.g., manifolds 22 and 23), each of said vapor phase reagent delivery manifolds interconnected with each other; each vessel connected to at least one vapor phase reagent delivery manifold; each vapor phase reagent delivery manifold comprising a vapor phase reagent discharge line (e.g., 34 and 44) extending from the vapor phase reagent outlet opening upwardly and exteriorly from the top wall member for removal of vapor phase reagent from said vessel, the vapor phase reagent discharge line optionally containing one or more vapor phase reagent flow control valves (e.g., V-7, V-9, V-15 and V-16 for ampoule 20; and V-12, V-13, V-14 and V-17 for ampoule 21) therein for control of flow of the vapor phase reagent therethrough; and

one or more controllers (not shown) for directing communication with each of said vapor phase reagent delivery manifolds (e.g., 22 and 23) and each of said vessels (e.g., 20 and 21), in such a way that each of said vapor phase reagent delivery manifolds are operable independently of one another, and each of said vessels are operable independently of one another.

The integrated vapor phase reagent dispensing apparatus further comprises a plurality of carrier gas feed manifolds (e.g., 24 and 25), each of said carrier gas feed manifolds connected to at least one vapor phase reagent delivery manifold (e.g., 22 and 23); each carrier gas feed manifold comprising a carrier gas feed line (e.g., 32 and 42); the carrier gas feed line containing one or more carrier gas flow control valves (e.g., V-1 for ampoule 20; and V-5 for ampoule 21) therein for control of flow of the carrier gas therethrough, and a pressure transducer (e.g., PTA and PTB) for monitoring and controlling the pressure of the carrier gas feed manifold.

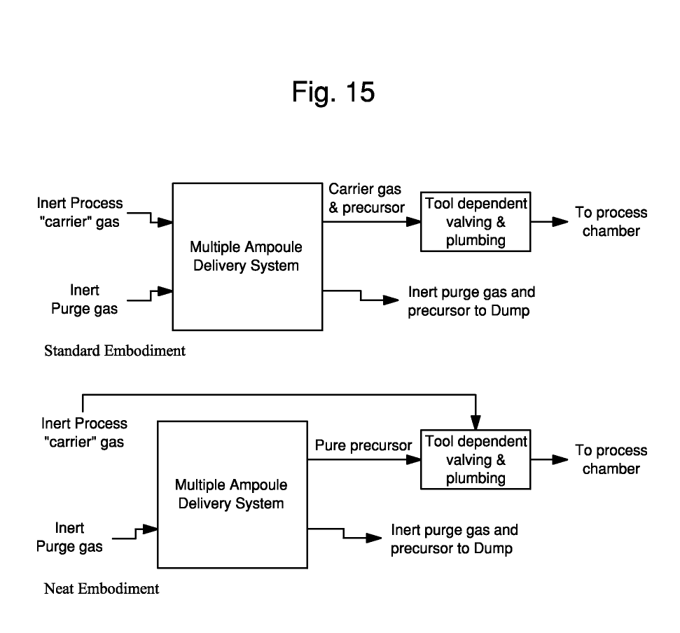

A simplified schematic representation of an integrated vapor or liquid phase reagent dispensing apparatus showing one embodiment of carrier gas and precursor being discharged from the multiple ampoule delivery system and another embodiment of pure precursor being discharged from the multiple ampoule delivery system (neat delivery) is shown in FIG. 15.

Referring to FIG. 16, this invention relates in part to a method for delivery of a vapor phase reagent to a deposition chamber comprising:

a. Providing an Integrated Vapor Phase Reagent Dispensing Apparatus Comprising:

a plurality of vessels (e.g., vessels 20 and 21), each vessel comprising a top wall member, a sidewall member and a bottom wall member configured to form an internal vessel compartment to hold a source chemical; and a portion of the top wall member having a vapor phase reagent outlet opening through which said vapor phase reagent can be dispensed from said vessel;

a plurality of vapor phase reagent delivery manifolds (e.g., manifolds 22 and 23), each of said vapor phase reagent delivery manifolds interconnected with each other; each vessel connected to at least one vapor phase reagent delivery manifold; each vapor phase reagent delivery manifold comprising a vapor phase reagent discharge line (e.g., 34 and 44) extending from the vapor phase reagent outlet opening upwardly and exteriorly from the top wall member for removal of vapor phase reagent from said inner gas volume above the fill level, the vapor phase reagent discharge line optionally containing one or more vapor phase reagent flow control valves (e.g., V-7, V-9, V-15 and V-16 for ampoule 20; and V-12, V-13, V-14 and V-17 for ampoule 21) therein for control of flow of the vapor phase reagent therethrough; and

one or more controllers (not shown) for directing communication with each of said vapor phase reagent delivery manifolds (e.g., 22 and 23) and each of said vessels (e.g., 20 and 21), in such a way that each of said vapor phase reagent delivery manifolds are operable independently of one another, and each of said vessels are operable independently of one another;

adding source chemical to one or more of said vessels (e.g., 20 or 21);

optionally heating the source chemical in one or more of said vessels (e.g., 20 or 21) to a temperature sufficient to vaporize the source chemical to provide vapor phase reagent;

withdrawing the vapor phase reagent from one of said vessels, independently of any other of said vessels, through said vapor phase reagent discharge line;

feeding a carrier gas into one or more of said vapor phase reagent delivery manifolds through a carrier gas feed line (e.g., 32 or 42) to mix with said vapor phase reagent; and

feeding the vapor phase reagent and carrier gas into said deposition chamber.

The above method further comprises:

contacting the vapor phase reagent with a substrate, optionally on a heatable susceptor, within the deposition chamber; and

discharging any remaining effluent through an effluent discharge line connected to the deposition chamber.

The integrated vapor phase reagent dispensing apparatus used in the method above further comprises a plurality of carrier gas feed manifolds (e.g., 24 or 25), each of said carrier gas feed manifolds connected to at least one vapor phase reagent delivery manifold (e.g., 22 and 23); each carrier gas feed manifold comprising a carrier gas feed line (e.g., 32 and 42); the carrier gas feed line containing one or more carrier gas flow control valves (e.g., V-1 for ampoule 20; and V-5 for ampoule 21) therein for control of flow of the carrier gas therethrough, and a pressure transducer (e.g., PTA and PTB) for monitoring and controlling the pressure of the carrier gas feed manifold.

In operation of the integrated vapor phase reagent dispensing apparatus depicted in FIG. 16, source chemical (e.g., AlCl₃) is placed in a vessel (e.g., 20 or 21) and heated to a temperature sufficient to vaporize the source chemical. The vapor phase reagent is discharged from the vessel through the vapor phase reagent outlet opening and the vapor phase reagent discharge line (e.g., 34 or 44). The neat precursor vapor may pass through a control valve or other instrumentation (e.g., I-1) before being diluted with an inert process carrier gas (from line 56) and continuing on to the deposition chamber. Vapor phase reagent flow control valves (e.g., V-7, V-9, V-15 and V-16 for ampoule 20; and V-12, V-13, V-14 and V-17 for ampoule 21) control the flow of the vapor phase reagent that is flowed to the deposition chamber. In the deposition chamber, the vapor phase reagent is deposited onto the wafer(s) or other substrate element(s) that are mounted on a heatable substrate or other mount structure. Effluent vapor from the deposition chamber is discharged in an effluent discharge line. The effluent may be passed to recycle, recovery, waste treatment, disposal, or other disposition means. In this embodiment, inert gas purge lines 32 and 42 can be used to purge residual precursor or air from the lines before and after an ampoule swap.

During this operation, the source chemical fill level in the vessel can be detected by a source chemical level sensor. It is important to know when the liquid precursor chemical inside of the vessel is close to running out so that it can be changed prior to the next chemical vapor deposition or atomic layer deposition run. The source chemical level progressively declines and eventually lowers into the sump cavity to a minimum liquid head (height of liquid, for example, in the sump cavity), at which point the controller or central processing unit receives a corresponding sensed source chemical level signal by a source chemical level sensing signal transmission line. The controller or central processing unit responsively transmits a control signal in a control signal transmission line to certain carrier gas flow control valves to close the valves and shut off the flow of carrier gas to the vessel, and also concurrently transmits a control signal in a control signal transmission line to close certain vapor phase reagent flow control valves, to shut off the flow of vapor phase reagent from the vessel.

Also, during this operation, the temperature of the source chemical in vessel can be detected by a temperature sensor. It is important to monitor the temperature of the liquid precursor chemical inside of the vessel to control the vapor pressure. If the temperature of the source chemical in the vessel becomes too high, the controller or central processing unit receives a corresponding sensed temperature signal by a temperature sensing signal transmission line. The controller or central processing unit responsively transmits a control signal in a control signal transmission line to a heating means to decrease the temperature.

The deposition chamber can be a chemical vapor deposition chamber or an atomic layer deposition chamber. The vapor phase reagent discharge line (e.g., 34 or 44) connects the vapor phase reagent dispensing apparatus to the deposition chamber. A heatable susceptor may be contained within the deposition chamber and is located in a receiving relationship to the vapor phase reagent discharge line (e.g., 34 or 44). An effluent discharge line is connected to the deposition chamber. The vapor phase reagent passes through the vapor phase reagent discharge line (e.g., 34 or 44) and into the deposition chamber, for contact with a substrate, optionally on the heatable susceptor, and any remaining effluent is discharged through the effluent discharge line. The effluent may be passed to recycle, recovery, waste treatment, disposal, or other disposition means.

The integrated vapor or liquid phase reagent dispensing apparatus of this invention may be useful for vaporization of liquids and solid materials, e.g., liquid and solid source reagents used in chemical vapor deposition, atomic layer deposition and ion implantation processes. See, for example, U.S. Pat. No. 6,921,062 B2; U.S. Patent Application Ser. No. 60/898,121, filed Jan. 29, 2007; U.S. Patent Application Ser. No. 60/903,720, filed Feb. 27, 2007; U.S. patent application Ser. No. 11/013,434, filed Dec. 17, 2004; U.S. Patent Application Ser. No. 60/897,947, filed Jan. 29, 2007; and U.S. Patent Application Ser. No. 60/903,579, filed Feb. 27, 2007; the disclosures of which are incorporated herein by reference.

Referring to FIGS. 1, 5 and 14, this invention relates in part to an integrated vapor phase reagent dispensing apparatus comprising:

a plurality of vessels (e.g., 20 and 21), each vessel comprising a top wall member, a sidewall member and a bottom wall member configured to form an internal vessel compartment to hold a source chemical up to a fill level and to additionally define an inner gas volume above the fill level; a portion of the top wall member having a carrier gas feed inlet opening through which carrier gas can be fed into said inner gas volume above the fill level to cause vapor of said source chemical to become entrained in said carrier gas to produce vapor phase reagent; and a portion of the top wall member having a vapor phase reagent outlet opening through which said vapor phase reagent can be dispensed from said vessel;

a plurality of carrier gas feed/vapor phase reagent delivery manifolds (e.g., manifolds 22 and 23), each of said carrier gas feed/vapor phase reagent delivery manifolds interconnected with each other; each vessel connected to at least one carrier gas feed/vapor phase reagent delivery manifold; each carrier gas feed/vapor phase reagent delivery manifold comprising a carrier gas feed line (e.g., 32 and 42 in FIG. 14) and a vapor phase reagent discharge line (e.g., 34 and 44 in FIG. 14); said carrier gas feed line extending from the carrier gas feed inlet opening upwardly and exteriorly from the top wall member for delivery of carrier gas into said inner gas volume above the fill level, the carrier gas feed line containing one or more carrier gas flow control valves (e.g., V-1, V-3, V-6 and V-8 for ampoule 20; and V-4, V-5, V-11 and V-18 for ampoule 21) therein for control of flow of the carrier gas therethrough; and said vapor phase reagent discharge line extending from the vapor phase reagent outlet opening upwardly and exteriorly from the top wall member for removal of vapor phase reagent from said inner gas volume above the fill level, the vapor phase reagent discharge line optionally containing one or more vapor phase reagent flow control valves (e.g., V-7, V-9, V-15 and V-16 for ampoule 20; and V-12, V-13, V-14 and V-17 for ampoule 21) therein for control of flow of the vapor phase reagent therethrough; and

one or more controllers (not shown) for directing communication with each of said carrier gas feed/vapor phase reagent delivery manifolds (e.g., 22 and 23) and each of said vessels (e.g., 20 and 21), in such a way that each of said carrier gas feed/vapor phase reagent delivery manifolds are operable independently of one another, and each of said vessels are operable independently of one another.

The integrated vapor phase reagent dispensing apparatus further comprises a plurality of sourcing gas manifolds (e.g., 24 and 25), each of said sourcing gas manifolds interconnected with each other; each sourcing gas manifold connected to at least one carrier gas feed/vapor phase reagent delivery manifold (e.g., 22 and 23); each sourcing gas manifold comprising a carrier gas feed line (e.g., 32 and 42 in FIG. 14) continuous with said carrier gas feed line of said carrier gas feed/vapor phase reagent delivery manifold; the carrier gas feed line containing one or more carrier gas flow control valves (e.g., V-1, V-3, V-6 and V-8 for ampoule 20; and V-4, V-5, V-11 and V-18 for ampoule 21) therein for control of flow of the carrier gas therethrough, and a pressure transducer (e.g., PTA and PTB) for monitoring and controlling the pressure of the sourcing gas manifold.

Referring to FIGS. 1, 5 and 14, this invention relates in part to a method for delivery of a vapor phase reagent to a deposition chamber comprising:

a. Providing an Integrated Vapor Phase Reagent Dispensing Apparatus Comprising:

a plurality of vessels (e.g., vessels 20 and 21), each vessel comprising a top wall member, a sidewall member and a bottom wall member configured to form an internal vessel compartment to hold a source chemical up to a fill level and to additionally define an inner gas volume above the fill level; a portion of the top wall member having a carrier gas feed inlet opening through which carrier gas can be fed into said inner gas volume above the fill level to cause vapor of said source chemical to become entrained in said carrier gas to produce vapor phase reagent; and a portion of the top wall member having a vapor phase reagent outlet opening through which said vapor phase reagent can be dispensed from said vessel;

a plurality of carrier gas feed/vapor phase reagent delivery manifolds (e.g., manifolds 22 and 23), each of said carrier gas feed/vapor phase reagent delivery manifolds interconnected with each other; each vessel connected to at least one carrier gas feed/vapor phase reagent delivery manifold; each carrier gas feed/vapor phase reagent delivery manifold comprising a carrier gas feed line (e.g., 32 and 42 in FIG. 14) and a vapor phase reagent discharge line (e.g., 34 and 44 in FIG. 14); said carrier gas feed line extending from the carrier gas feed inlet opening upwardly and exteriorly from the top wall member for delivery of carrier gas into said inner gas volume above the fill level, the carrier gas feed line containing one or more carrier gas flow control valves (e.g., V-1, V-3, V-6 and V-8 for ampoule 20; and V-4, V-5, V-11 and V-18 for ampoule 21) therein for control of flow of the carrier gas therethrough; and said vapor phase reagent discharge line extending from the vapor phase reagent outlet opening upwardly and exteriorly from the top wall member for removal of vapor phase reagent from said inner gas volume above the fill level, the vapor phase reagent discharge line optionally containing one or more vapor phase reagent flow control valves (e.g., V-7, V-9, V-15 and V-16 for ampoule 20; and V-12, V-13, V-14 and V-17 for ampoule 21) therein for control of flow of the vapor phase reagent therethrough; and

one or more controllers for directing communication with each of said carrier gas feed/vapor phase reagent delivery manifolds (e.g., 22 and 23) and each of said vessels (e.g., 20 and 21), in such a way that each of said carrier gas feed/vapor phase reagent delivery manifolds are operable independently of one another, and each of said vessels are operable independently of one another;

adding source chemical to one or more of said vessels (e.g., 20 or 21);

heating the source chemical in one or more of said vessels (e.g., 20 or 21) to a temperature sufficient to vaporize the source chemical to provide vapor phase reagent;

feeding a carrier gas into one or more of said vessels through said carrier gas feed line (e.g., 32 or 42 in FIG. 14);

withdrawing the vapor phase reagent and carrier gas from one of said vessels (e.g., 20 or 21), independently of any other of said vessels, through said vapor phase reagent discharge line (e.g., 34 or 44 in FIG. 14); and

feeding the vapor phase reagent and carrier gas into said deposition chamber.

The above method further comprises:

contacting the vapor phase reagent with a substrate, optionally on a heatable susceptor, within the deposition chamber; and

discharging any remaining effluent through an effluent discharge line connected to the deposition chamber.

The integrated vapor phase reagent dispensing apparatus used in the method above further comprises a plurality of sourcing gas manifolds (e.g., 24 or 25), each of said sourcing gas manifolds interconnected with each other; each sourcing gas manifold connected to at least one carrier gas feed/vapor phase reagent delivery manifold (e.g., 22 and 23); each sourcing gas manifold comprising a carrier gas feed line (e.g., 32 and 42 in FIG. 14) continuous with said carrier gas feed line of said carrier gas feed/vapor phase reagent delivery manifold; the carrier gas feed line containing one or more carrier gas flow control valves (e.g., V-1, V-3, V-6 and V-8 for ampoule 20; and V-4, V-5, V-11 and V-18 for ampoule 21) therein for control of flow of the carrier gas therethrough, and a pressure transducer (e.g., PTA and PTB) for monitoring and controlling the pressure of the sourcing gas manifold.

In operation of the integrated vapor phase reagent dispensing apparatus depicted in FIGS. 1, 5 and 14, source chemical is placed in a vessel (e.g., 20 or 21) and heated to a temperature sufficient to vaporize the source chemical. Carrier gas is allowed to flow through the carrier gas feed line (e.g., 32 or 42 in FIG. 14) to the carrier gas feed inlet opening from which it is discharged into the inner gas volume above the fill level. Carrier gas flow control valves (e.g., V-1, V-3, V-6 and V-8 for ampoule 20; and V-4, V-5, V-11 and V-18 for ampoule 21) control the flow of the carrier gas that is discharged into the inner gas volume. Vapor from the source chemical becomes entrained in the carrier gas to produce vapor phase reagent.

The vapor phase reagent is discharged from the inner gas volume through the vapor phase reagent outlet opening and the vapor phase reagent discharge line (e.g., 34 or 44 in FIG. 14). The vapor phase reagent is flowed in the vapor phase reagent discharge line (e.g., 34 or 44 in FIG. 14) to the deposition chamber. Vapor phase reagent flow control valves (e.g., V-7, V-9, V-15 and V-16 for ampoule 20; and V-12, V-13, V-14 and V-17 for ampoule 21) control the flow of the vapor phase reagent that is flowed to the deposition chamber. In the deposition chamber, the vapor phase reagent is deposited onto the wafer(s) or other substrate element(s) that are mounted on a heatable substrate or other mount structure. Effluent vapor from the deposition chamber is discharged in an effluent discharge line. The effluent may be passed to recycle, recovery, waste treatment, disposal, or other disposition means.

During this operation, the source chemical fill level in the vessel can be detected by a source chemical level sensor. It is important to know when the liquid precursor chemical inside of the vessel is close to running out so that it can be changed prior to the next chemical vapor deposition or atomic layer deposition run. The source chemical level progressively declines and eventually lowers into the sump cavity to a minimum liquid head (height of liquid, for example, in the sump cavity), at which point the controller or central processing unit receives a corresponding sensed source chemical level signal by a source chemical level sensing signal transmission line. The controller or central processing unit responsively transmits a control signal in a control signal transmission line to certain carrier gas flow control valves to close the valves and shut off the flow of carrier gas to the vessel, and also concurrently transmits a control signal in a control signal transmission line to close certain vapor phase reagent flow control valves, to shut off the flow of vapor phase reagent from the vessel.

In the case where auto-switchover from one ampoule to another is enabled, the system would require information regarding the amount of material remaining in an ampoule, usage per run and a signal from the tool that a run was in progress so as not to enable switchover during a run, but rather between a run of wafers or batches of wafers. Standard industry practice typically involves performing a re-qualification run after switchover and the system would alert the operator that auto-switchover has taken place.

Also, during this operation, the temperature of the vessel can be detected by a temperature sensor. It is important to monitor the temperature of the vessel (e.g., thermowell for liquids or representative spot on a solid-source ampoule) to control the vapor pressure. If the temperature of the source chemical in the vessel becomes too high, the controller or central processing unit receives a corresponding sensed temperature signal by a temperature sensing signal transmission line. The controller or central processing unit responsively transmits a control signal in a control signal transmission line to a heating means to decrease the temperature.

The deposition chamber can be a chemical vapor deposition chamber or an atomic layer deposition chamber. The vapor phase reagent discharge line (e.g., 34 or 44 in FIG. 14) connects the vapor phase reagent dispensing apparatus to the deposition chamber. A heatable susceptor or deposition substrate may be contained within the deposition chamber and is located in a receiving relationship to the vapor phase reagent discharge line (e.g., 34 or 44 in FIG. 14). An effluent discharge line is connected to the deposition chamber. The vapor phase reagent passes through the vapor phase reagent discharge line (e.g., 34 or 44 in FIG. 14) and into the deposition chamber, for contact with a substrate, optionally on the heatable susceptor, and any remaining effluent is discharged through the effluent discharge line. The effluent may be passed to recycle, recovery, waste treatment, disposal, or other disposition means.

The integrated vapor or liquid phase reagent dispensing apparatus of this invention may be useful for vaporization of liquids and solid materials, e.g., liquid and solid source reagents used in chemical vapor deposition, atomic layer deposition and ion implantation processes. See, for example, U.S. Pat. No. 6,921,062 B2; U.S. Patent Application Ser. No. 60/898,121, filed Jan. 29, 2007; U.S. Patent Application Ser. No. 60/903,720, filed Feb. 27, 2007; U.S. patent application Ser. No. 11/013,434, filed Dec. 17, 2004; U.S. patent application Ser. No. 60/897,947, filed Jan. 29, 2007; and U.S. Patent Application Ser. No. 60/903,579, filed Feb. 27, 2007; the disclosures of which are incorporated herein by reference.

Referring to FIGS. 1, 5 and 14, this invention relates in part to an integrated vapor phase reagent dispensing apparatus comprising:

a plurality of vessels (e.g., vessels 20 and 21), each vessel comprising a top wall member, a sidewall member and a bottom wall member configured to form an internal vessel compartment to hold a source chemical up to a fill level and to additionally define an inner gas volume above the fill level; a portion of the top wall member having a carrier gas feed inlet opening comprising a bubbler tube that extends through the inner gas volume into the source chemical and through which said carrier gas can be bubbled into the source chemical to cause at least a portion of source chemical vapor to become entrained in said carrier gas to produce a flow of vapor phase reagent to said inner gas volume above the fill level, said bubbler tube having an inlet end adjacent to the top wall member and an outlet end adjacent to the bottom wall member; and a portion of the top wall member having a vapor phase reagent outlet opening through which said vapor phase reagent can be dispensed from said vessel; and

a plurality of carrier gas feed/vapor phase reagent delivery manifolds (e.g., vessels 22 and 23), each of said carrier gas feed/vapor phase reagent delivery manifolds interconnected with each other; each vessel connected to at least one carrier gas feed/vapor phase reagent delivery manifold; each carrier gas feed/vapor phase reagent delivery manifold comprising a carrier gas feed line (e.g., 32 and 42 in FIG. 14) and a vapor phase reagent discharge line (e.g., 34 and 44 in FIG. 14); said carrier gas feed line extending from the carrier gas feed inlet opening upwardly and exteriorly from the top wall member for delivery of carrier gas into said inner gas volume above the fill level, the carrier gas feed line containing one or more carrier gas flow control valves (e.g., V-1, V-3, V-6 and V-8 for ampoule 20; and V-4, V-5, V-11 and V-18 for ampoule 21) therein for control of flow of the carrier gas therethrough; and said vapor phase reagent discharge line extending from the vapor phase reagent outlet opening upwardly and exteriorly from the top wall member for removal of vapor phase reagent from said inner gas volume above the fill level, the vapor phase reagent discharge line optionally containing one or more vapor phase reagent flow control valves (e.g., V-7, V-9, V-15 and V-16 for ampoule 20; and V-12, V-13, V-14 and V-17 for ampoule 21) therein for control of flow of the vapor phase reagent therethrough; and

one or more controllers for directing communication with each of said carrier gas feed/vapor phase reagent delivery manifolds (e.g., vessels 22 and 23) and each of said vessels (e.g., vessels 20 and 21), in such a way that each of said carrier gas feed/vapor phase reagent delivery manifolds are operable independently of one another, and each of said vessels are operable independently of one another.

The integrated vapor phase reagent dispensing apparatus further comprises a plurality of sourcing gas manifolds (e.g., vessels 24 and 25), each of said sourcing gas manifolds interconnected with each other; each sourcing gas manifold connected to at least one carrier gas feed/vapor phase reagent delivery manifold (e.g., 22 and 23); each sourcing gas manifold comprising a carrier gas feed line (e.g., 32 and 34 in FIG. 14) continuous with said carrier gas feed line of said carrier gas feed/vapor phase reagent delivery manifold; the carrier gas feed line containing one or more carrier gas flow control valves (e.g., V-1, V-3, V-6 and V-8 for ampoule 20; and V-4, V-5, V-11 and V-18 for ampoule 21) therein for control of flow of the carrier gas therethrough, and a pressure transducer (e.g., PTA and PTB) for monitoring and controlling the pressure of the sourcing gas manifold.

Referring to FIGS. 1, 5 and 14, this invention relates in part to a method for delivery of a vapor phase reagent to a deposition chamber comprising:

a. Providing an Integrated Vapor Phase Reagent Dispensing Apparatus Comprising:

a plurality of vessels (e.g., vessels 20 and 21), each vessel comprising a top wall member, a sidewall member and a bottom wall member configured to form an internal vessel compartment to hold a source chemical up to a fill level and to additionally define an inner gas volume above the fill level; a portion of the top wall member having a carrier gas feed inlet opening comprising a bubbler tube that extends through the inner gas volume into the source chemical and through which said carrier gas can be bubbled into the source chemical to cause at least a portion of source chemical vapor to become entrained in said carrier gas to produce a flow of vapor phase reagent to said inner gas volume above the fill level, said bubbler tube having an inlet end adjacent to the top wall member and an outlet end adjacent to the bottom wall member; and a portion of the top wall member having a vapor phase reagent outlet opening through which said vapor phase reagent can be dispensed from said vessel; and

a plurality of carrier gas feed/vapor phase reagent delivery manifolds (e.g., 22 and 23), each of said carrier gas feed/vapor phase reagent delivery manifolds interconnected with each other; each vessel connected to at least one carrier gas feed/vapor phase reagent delivery manifold; each carrier gas feed/vapor phase reagent delivery manifold comprising a carrier gas feed line (e.g., 32 and 42 in FIG. 14) and a vapor phase reagent discharge line (e.g., 34 and 44 in FIG. 14); said carrier gas feed line extending from the carrier gas feed inlet opening upwardly and exteriorly from the top wall member for delivery of carrier gas into said inner gas volume above the fill level, the carrier gas feed line containing one or more carrier gas flow control valves (e.g., V-1, V-3, V-6 and V-8 for ampoule 20; and V-4, V-5, V-11 and V-18 for ampoule 21) therein for control of flow of the carrier gas therethrough; and said vapor phase reagent discharge line extending from the vapor phase reagent outlet opening upwardly and exteriorly from the top wall member for removal of vapor phase reagent from said inner gas volume above the fill level, the vapor phase reagent discharge line optionally containing one or more vapor phase reagent flow control valves (e.g., V-7, V-9, V-15 and V-16 for ampoule 20; and V-12, V-13, V-14 and V-17 for ampoule 21) therein for control of flow of the vapor phase reagent therethrough; and

one or more controllers for directing communication with each of said carrier gas feed/vapor phase reagent delivery manifolds (e.g., vessels 22 and 23) and each of said vessels (e.g., vessels 20 and 21), in such a way that each of said carrier gas feed/vapor phase reagent delivery manifolds are operable independently of one another, and each of said vessels are operable independently of one another;

adding source chemical to one or more of said vessels (e.g., 20 or 21);

heating the source chemical in one or more of said vessels (e.g., 20 or 21) to a temperature sufficient to vaporize the source chemical to provide vapor phase reagent;

feeding a carrier gas into one or more of said vessels through said carrier gas feed line (e.g., 32 or 42 in FIG. 14) and said bubbler tube;

withdrawing the vapor phase reagent and carrier gas from one of said vessels (e.g., 20 or 21), independently of any other of said vessels, through said vapor phase reagent discharge line (e.g., 34 or 44 in FIG. 14); and

feeding the vapor phase reagent and carrier gas into said deposition chamber.

The above method further comprises:

contacting the vapor phase reagent with a substrate, optionally on a heatable susceptor, within the deposition chamber; and

discharging any remaining effluent through an effluent discharge line connected to the deposition chamber.

The integrated vapor phase reagent dispensing apparatus used in the method above further comprises a plurality of sourcing gas manifolds (e.g., 24 and 25), each of said sourcing gas manifolds interconnected with each other; each sourcing gas manifold connected to at least one carrier gas feed/vapor phase reagent delivery manifold (e.g., 22 and 23); each sourcing gas manifold comprising a carrier gas feed line (e.g., 32 and 42 in FIG. 14) continuous with said carrier gas feed line of said carrier gas feed/vapor phase reagent delivery manifold; the carrier gas feed line containing one or more carrier gas flow control valves (e.g., V-1, V-3, V-6 and V-8 for ampoule 20; and V-4, V-5, V-11 and V-18 for ampoule 21) therein for control of flow of the carrier gas therethrough, and a pressure transducer (e.g., PTA and PTB) for monitoring and controlling the pressure of the sourcing gas manifold.

In operation of the integrated vapor phase reagent dispensing apparatus depicted in FIGS. 1, 5 and 18, source chemical is placed in the vessel (e.g., 20 or 21) and heated to a temperature sufficient to vaporize the source chemical. Carrier gas is allowed to flow through the carrier gas feed line (e.g., 32 or 42 in FIG. 14) to the carrier gas feed inlet opening and through bubbler tube from which it is bubbled into the source chemical. Carrier gas flow control valves (e.g., V-1, V-3, V-6 and V-8 for ampoule 20; and V-4, V-5, V-11 and V-18 for ampoule 21) control the flow of the carrier gas that is discharged into the source chemical. Vapor from the source chemical becomes entrained in the carrier gas to produce vapor phase reagent.

The vapor phase reagent is discharged from the inner gas volume through the vapor phase reagent outlet opening and the vapor phase reagent discharge line (e.g., 34 or 44 in FIG. 14). The vapor phase reagent is flowed in the vapor phase reagent discharge line (e.g., 34 or 44 in FIG. 14) to the deposition chamber. Vapor phase reagent flow control valves (e.g., V-7, V-9, V-15 and V-16 for ampoule 20; and V-12, V-13, V-14 and V-17 for ampoule 21) control the flow of the vapor phase reagent that is flowed to the deposition chamber. In the deposition chamber, the vapor phase reagent is deposited onto the wafer(s) or other substrate element(s) that are mounted on a heatable substrate or other mount structure. Effluent vapor from the deposition chamber is discharged in an effluent discharge line. The effluent may be passed to recycle, recovery, waste treatment, disposal, or other disposition means.

During this operation, the source chemical fill level in the vessel can be detected by a source chemical level sensor. It is important to know when the liquid precursor chemical inside of the vessel is close to running out so that it can be changed prior to the next chemical vapor deposition or atomic layer deposition run. The source chemical level progressively declines and eventually lowers into the sump cavity to a minimum liquid head (height of liquid, for example, in the sump cavity), at which point the central processing unit receives a corresponding sensed source chemical level signal by a source chemical level sensing signal transmission line. The central processing unit responsively transmits a control signal in a control signal transmission line to the carrier gas flow control valve to close the valve and shut off the flow of carrier gas to the vessel, and also concurrently transmits a control signal in a control signal transmission line to close the vapor phase reagent flow control valve, to shut off the flow of vapor phase reagent from the vessel.

Also, during this operation, the temperature of the source chemical in vessel is detected by a temperature sensor. It is important to monitor the temperature of the liquid precursor chemical inside of the vessel to control the vapor pressure. If the temperature of the source chemical in the vessel becomes too high, the controller or central processing unit receives a corresponding sensed temperature signal by a temperature sensing signal transmission line. The controller or central processing unit responsively transmits a control signal in a control signal transmission line to a heating means to decrease the temperature.

The deposition chamber can be a chemical vapor deposition chamber or an atomic layer deposition chamber. The vapor phase reagent discharge line (e.g., 34 or 44 in FIG. 14) connects the vapor phase reagent dispensing apparatus to the deposition chamber. A heatable susceptor may be contained within the deposition chamber and is located in a receiving relationship to the vapor phase reagent discharge line (e.g., 34 or 44 in FIG. 14). An effluent discharge line is connected to the deposition chamber. The vapor phase reagent passes through the vapor phase reagent discharge line (e.g., 34 or 44 in FIG. 14) and into the deposition chamber, for contact with a substrate, optionally on the heatable susceptor, and any remaining effluent is discharged through the effluent discharge line. The effluent may be passed to recycle, recovery, waste treatment, disposal, or other disposition means.

The integrated vapor phase reagent dispensing apparatus, i.e., bubbler, of this invention may be useful for vaporization of liquids and solid materials, e.g., liquid and solid source reagents used in chemical vapor deposition, atomic layer deposition and ion implantation processes. See, for example, U.S. Pat. No. 6,921,062 B2; U.S. Patent Application Ser. No. 60/898,121, filed Jan. 29, 2007; U.S. Patent Application Ser. No. 60/903,720, filed Feb. 27, 2007; U.S. patent application Ser. No. 11/013,434, filed Dec. 17, 2004; U.S. Patent Application Ser. No. 60/897,947, filed Jan. 29, 2007; and U.S. Patent Application Ser. No. 60/903,579, filed Feb. 27, 2007; the disclosures of which are incorporated herein by reference.

Referring to FIGS. 1, 5 and 14, this invention relates in part to an integrated liquid phase reagent dispensing apparatus comprising:

a plurality of vessels (e.g., 20 and 21), each vessel comprising a top wall member, a sidewall member and a bottom wall member configured to form an internal vessel compartment to hold a source chemical up to a fill level and to additionally define an inner gas volume above the fill level; a portion of the top wall member having an inert gas feed inlet opening through which said inert gas can be fed into the inner gas volume above the fill level to pressurize the inner gas volume above the fill level; and a portion of the top wall member having a liquid phase reagent outlet opening comprising a diptube that extends through the inner gas volume into the source chemical and through which liquid phase reagent can be dispensed from said apparatus, said diptube having an outlet end adjacent to the top wall member and an inlet end adjacent to the bottom wall member;

a plurality of inert gas feed/liquid phase reagent delivery manifolds (e.g., 22 and 23), each of said inert gas feed/liquid phase reagent delivery manifolds interconnected with each other; each vessel connected to at least one inert gas feed/liquid phase reagent delivery manifold; each inert gas feed/liquid phase reagent delivery manifold comprising an inert gas feed line (e.g., 32 and 42 in FIG. 14) and a liquid phase reagent discharge line (e.g., 34 and 44 in FIG. 14); said inert gas feed line extending from the inert gas feed inlet opening upwardly and exteriorly from the top wall member for delivery of inert gas into said inner gas volume above the fill level, the inert gas feed line containing one or more inert gas flow control valves (e.g., V-1, V-3, V-6 and V-8 for ampoule 20; and V-4, V-5, V-11 and V-18 for ampoule 21) therein for control of flow of the inert gas therethrough; and said liquid phase reagent discharge line extending from the liquid phase reagent outlet opening upwardly and exteriorly from the top wall member for removal of liquid phase reagent from said vessel, the liquid phase reagent discharge line optionally containing one or more liquid phase reagent flow control valves (e.g., V-7, V-9, V-15 and V-16 for ampoule 20; and V-12, V-13, V-14 and V-17 for ampoule 21) therein for control of flow of the liquid phase reagent therethrough; and

one or more controllers for directing communication with each of said inert gas feed/liquid phase reagent delivery manifolds (e.g., 22 and 23) and each of said vessels (e.g., 20 and 21), in such a way that each of said inert gas feed/liquid phase reagent delivery manifolds are operable independently of one another, and each of said vessels are operable independently of one another.

The integrated liquid phase reagent dispensing apparatus further comprises a plurality of sourcing gas manifolds (e.g., 24 and 25), each of said sourcing gas manifolds interconnected with each other; each sourcing gas manifold connected to at least one inert gas feed/liquid phase reagent delivery manifold (e.g., 22 and 23); each sourcing gas manifold comprising an inert gas feed line (e.g., 32 and 42 in FIG. 14) continuous with said inert gas feed line of said inert gas feed/liquid phase reagent delivery manifold; the inert gas feed line containing one or more inert gas flow control valves (e.g., V-1, V-3, V-6 and V-8 for ampoule 20; and V-4, V-5, V-11 and V-18 for ampoule 21) therein for control of flow of the inert gas therethrough, and a pressure transducer (e.g., PTA and PTB) for monitoring and controlling the pressure of the sourcing gas manifold.

Referring to FIGS. 1, 5 and 14, this invention relates in part to a method for delivery of a vapor phase reagent to a deposition chamber comprising:

a. Providing an Integrated Liquid Phase Reagent Dispensing Apparatus Comprising:

a plurality of vessels (e.g., 20 and 21), each vessel comprising a top wall member, a sidewall member and a bottom wall member configured to form an internal vessel compartment to hold a source chemical up to a fill level and to additionally define an inner gas volume above the fill level; a portion of the top wall member having an inert gas feed inlet opening through which said inert gas can be fed into the inner gas volume above the fill level to pressurize the inner gas volume above the fill level; and a portion of the top wall member having a liquid phase reagent outlet opening comprising a diptube that extends through the inner gas volume into the source chemical and through which liquid phase reagent can be dispensed from said apparatus, said diptube having an outlet end adjacent to the top wall member and an inlet end adjacent to the bottom wall member;

a plurality of inert gas feed/liquid phase reagent delivery manifolds (e.g., 22 and 23), each of said inert gas feed/liquid phase reagent delivery manifolds interconnected with each other; each vessel connected to at least one inert gas feed/liquid phase reagent delivery manifold; each inert gas feed/liquid phase reagent delivery manifold comprising an inert gas feed line (e.g., 32 and 42 in FIG. 14) and a liquid phase reagent discharge line (e.g., 34 and 44 in FIG. 14); said inert gas feed line extending from the inert gas feed inlet opening upwardly and exteriorly from the top wall member for delivery of inert gas into said inner gas volume above the fill level, the inert gas feed line containing one or more inert gas flow control valves (e.g., V-1, V-3, V-6 and V-8 for ampoule 20; and V-4, V-5, V-11 and V-18 for ampoule 21) therein for control of flow of the inert gas therethrough; and said liquid phase reagent discharge line extending from the liquid phase reagent outlet opening upwardly and exteriorly from the top wall member for removal of liquid phase reagent from said vessel, the liquid phase reagent discharge line optionally containing one or more liquid phase reagent flow control valves (e.g., V-7, V-9, V-15 and V-16 for ampoule 20; and V-12, V-13, V-14 and V-17 for ampoule 21) therein for control of flow of the liquid phase reagent therethrough; and

one or more controllers for directing communication with each of said inert gas feed/liquid phase reagent delivery manifolds (e.g., 22 and 23) and each of said vessels (e.g., 20 and 21), in such a way that each of said inert gas feed/liquid phase reagent delivery manifolds are operable independently of one another, and each of said vessels are operable independently of one another;

adding source chemical to one or more of said vessels (e.g., 20 or 21);

optionally heating a solid source chemical in one or more of said vessels (e.g., 20 or 21) to a temperature sufficient to melt the solid source chemical to provide liquid phase reagent;

feeding an inert gas into one or more of said vessels through said inert gas feed line (e.g., 32 or 42 in FIG. 14);

withdrawing liquid phase reagent from one of said vessels, independently of any other of said vessels (e.g., 20 or 21), through said diptube and said liquid phase reagent discharge line (e.g., 34 or 44 in FIG. 14);

providing a vaporization apparatus comprising:

a vessel which comprises a top wall member, a sidewall member and a bottom wall member configured to form an internal vessel compartment to vaporize the liquid phase reagent;

said liquid phase reagent discharge line connecting the integrated liquid phase reagent dispensing apparatus to said vaporization apparatus;

a portion of the vaporization apparatus having a carrier gas feed inlet opening through which carrier gas can be fed into said vaporization apparatus to cause vapor of said liquid phase reagent to become entrained in said carrier gas to produce vapor phase reagent;

a portion of the vaporization apparatus having a vapor phase reagent outlet opening through which said vapor phase reagent can be dispensed from said vaporization apparatus;

a carrier gas feed line extending from the carrier gas feed inlet opening upwardly and exteriorly from the vaporization apparatus for delivery of carrier gas into said vaporization apparatus, the carrier gas feed line containing one or more carrier gas flow control valves therein for control of flow of the carrier gas therethrough;

a vapor phase reagent discharge line extending from the vapor phase reagent outlet opening upwardly and exteriorly from the vaporization apparatus for removal of vapor phase reagent from said vaporization apparatus to said deposition chamber, the vapor phase reagent discharge line containing one or more vapor phase reagent flow control valves therein for control of flow of the vapor phase reagent therethrough;

feeding the liquid phase reagent into said vaporization apparatus;

heating the liquid phase reagent in said vaporization apparatus to a temperature sufficient to vaporize the liquid phase reagent to provide said vapor phase reagent;

feeding a carrier gas into said vaporization apparatus through said carrier gas feed line;

withdrawing the vapor phase reagent and carrier gas from said vaporization apparatus through said vapor phase reagent discharge line; and

feeding the vapor phase reagent and carrier gas into said deposition chamber.

The above method further comprises:

contacting the vapor phase reagent with a substrate, optionally on a heatable susceptor, within the deposition chamber; and

discharging any remaining effluent through an effluent discharge line connected to the deposition chamber.

The integrated liquid phase reagent dispensing apparatus used in the above method further comprises a plurality of sourcing gas manifolds (e.g., 24 and 25), each of said sourcing gas manifolds interconnected with each other; each sourcing gas manifold connected to at least one inert gas feed/liquid phase reagent delivery manifold (e.g., 22 and 23); each sourcing gas manifold comprising an inert gas feed line (e.g., 32 and 42 in FIG. 14) continuous with said inert gas feed line of said inert gas feed/liquid phase reagent delivery manifold; the inert gas feed line containing one or more inert gas flow control valves (e.g., V-1, V-3, V-6 and V-8 for ampoule 20; and V-4, V-5, V-11 and V-18 for ampoule 21) therein for control of flow of the inert gas therethrough, and a pressure transducer (e.g., PTA and PTB) for monitoring and controlling the pressure of the sourcing gas manifold.

In operation of the integrated liquid phase reagent dispensing apparatus depicted in FIGS. 1, 5 and 18, source chemical is placed in the vessel (e.g., 20 or 21) and an inert gas is allowed to flow through the inert gas feed line (e.g., 32 or 42 in FIG. 14) to the inert gas feed inlet opening and into the inner gas volume above the fill level to pressurize the inner gas volume above the fill level. Inert gas flow control valves (e.g., V-1, V-3, V-6 and V-8 for ampoule 20; and V-4, V-5, V-11 and V-18 for ampoule 21) control the flow of the inert gas that is discharged into the inner gas volume above the fill level.

The liquid phase reagent is discharged from the vessel (e.g., 20 or 21) through liquid phase reagent outlet opening (e.g., diptube) and the liquid phase reagent discharge line (e.g., 34 or 44 in FIG. 14). The liquid phase reagent is flowed in the liquid phase reagent discharge line (e.g., 34 or 44 in FIG. 14) to the deposition chamber. Liquid phase reagent flow control valves (e.g., V-7, V-9, V-15 and V-16 for ampoule 20; and V-12, V-13, V-14 and V-17 for ampoule 21) control the flow of the liquid phase reagent that is flowed to the vaporization apparatus.

In vaporization apparatus, the liquid phase reagent is vaporized to form a source vapor for the subsequent vapor deposition operation. The vaporization apparatus may also receive a carrier gas for combining with or shrouding the source vapor produced by vaporization of the liquid phase reagent. Alternatively, the source vapor may be passed to the downstream vapor deposition operation in neat form. In any event, the source vapor from vaporization apparatus is flowed through vapor phase reagent discharge line to deposition chamber. In the deposition chamber, the vapor phase reagent is deposited onto the wafer(s) or other substrate element(s) that are mounted on a heatable substrate or other mount structure. Effluent vapor from the deposition chamber is discharged in effluent discharge line. The effluent may be passed to recycle, recovery, waste treatment, disposal, or other disposition means.

During this operation, the source chemical fill level in the vessel can be detected by a source chemical level sensor. It is important to know when the liquid precursor chemical inside of the vessel is close to running out so that it can be changed prior to the next chemical vapor deposition or atomic layer deposition run. The source chemical level progressively declines and eventually lowers into the sump cavity to a minimum liquid head (height of liquid, for example, in the sump cavity), at which point the central processing unit receives a corresponding sensed source chemical level signal by a source chemical level sensing signal transmission line. The central processing unit responsively transmits a control signal in a control signal transmission line to the carrier gas flow control valve to close the valve and shut off the flow of carrier gas to the vessel, and also concurrently transmits a control signal in a control signal transmission line to close the liquid phase reagent flow control valve, to shut off the flow of liquid reagent from the vessel.

Also, during this operation, the temperature of the source chemical in vessel is detected by a temperature sensor. It is important to monitor the temperature of the liquid precursor chemical inside of the vessel to control the vapor pressure. If the temperature of the source chemical in the vessel becomes too high, the central processing unit receives a corresponding sensed temperature signal by a temperature sensing signal transmission line. The central processing unit responsively transmits a control signal in a control signal transmission line to a heating means to decrease the temperature.

The integrated liquid phase reagent dispensing apparatus of this invention may be useful for dispensing of reagents such as precursors used in chemical vapor deposition, atomic layer deposition and ion implantation processes, and can achieve a high level of withdrawal of liquid reagent from the vessel. See, for example, U.S. Pat. No. 6,077,356; U.S. Patent Application Ser. No. 60/898,121, filed Jan. 29, 2007; U.S. Patent Application Ser. No. 60/903,720, filed Feb. 27, 2007; U.S. patent application Ser. No. 11/013,434, filed Dec. 17, 2004; U.S. Patent Application Ser. No. 60/897,947, filed Jan. 29, 2007; and U.S. Patent Application Ser. No. 60/903,579, filed Feb. 27, 2007; the disclosures of which are incorporated herein by reference.

The deposition chamber can be a chemical vapor deposition chamber or an atomic layer deposition chamber. The liquid phase reagent discharge line (e.g., 34 or 44 in FIG. 14) connects the liquid phase reagent dispensing apparatus to a vaporization apparatus. The vaporization apparatus has a carrier gas feed line extending from the carrier gas feed inlet opening upwardly and exteriorly from the vaporization apparatus through which carrier gas can be fed into the vaporization apparatus to cause vapor of said liquid phase reagent to become entrained in the carrier gas to produce vapor phase reagent. The carrier gas feed line contains a carrier gas flow control valve for control of flow of the carrier gas therethrough. The carrier gas feed line is coupled to a carrier gas source. The carrier gas source can be of any suitable type, for example, a high pressure gas cylinder, a cryogenic air separation plant, or a pressure swing air separation unit, furnishing a carrier gas, e.g., nitrogen, argon, helium, etc., to the carrier gas feed line.

The vaporization apparatus has a vapor phase reagent discharge line extending from the vapor phase reagent outlet opening upwardly and exteriorly from the vaporization apparatus through which the vapor phase reagent can be dispensed from the vaporization apparatus to the deposition chamber. The vapor phase reagent discharge line contains a vapor phase reagent flow control valve therein for control of flow of the vapor phase reagent therethrough.

A heatable susceptor may be contained within the deposition chamber and is located in a receiving relationship to the vapor phase reagent discharge line. An effluent discharge line is connected to the deposition chamber. The vapor phase reagent passes through the vapor phase reagent discharge line and into the deposition chamber, for contact with a substrate, optionally on the heatable susceptor, and any remaining effluent is discharged through the effluent discharge line. The effluent may be passed to recycle, recovery, waste treatment, disposal, or other disposition means.

In an embodiment of this invention, an organometallic compound is employed in vapor phase deposition techniques for forming powders, films or coatings. The compound can be employed as a single source precursor or can be used together with one or more other precursors, for instance, with vapor generated by heating at least one other organometallic compound or metal complex.

Deposition can be conducted in the presence of other vapor phase components. In an embodiment of the invention, film deposition is conducted in the presence of at least one non-reactive carrier gas. Examples of non-reactive gases include inert gases, e.g., nitrogen, argon, helium, as well as other gases that do not react with the organometallic compound precursor under process conditions. In other embodiments, film deposition is conducted in the presence of at least one reactive gas. Some of the reactive gases that can be employed include but are not limited to hydrazine, oxygen, hydrogen, air, oxygen-enriched air, ozone (O₃), nitrous oxide (N₂O), water vapor, organic vapors, ammonia and others. As known in the art, the presence of an oxidizing gas, such as, for example, air, oxygen, oxygen-enriched air, O₃, N₂O or a vapor of an oxidizing organic compound, favors the formation of a metal oxide film.

Deposition methods described herein can be conducted to form a film, powder or coating that includes a single metal or a film, powder or coating that includes a single metal oxide. Mixed films, powders or coatings also can be deposited, for instance mixed metal oxide films. A mixed metal oxide film can be formed, for example, by employing several organometallic precursors, at least one of which being selected from the organometallic compounds described above.

Vapor phase film deposition can be conducted to form film layers of a desired thickness, for example, in the range of from less than 1 nm to over 1 mm. The precursors described herein are particularly useful for producing thin films, e.g., films having a thickness in the range of from about 10 nm to about 100 nm. Films of this invention, for instance, can be considered for fabricating metal electrodes, in particular as n-channel metal electrodes in logic, as capacitor electrodes for DRAM applications, and as dielectric materials.

The deposition method also is suited for preparing layered films, wherein at least two of the layers differ in phase or composition. Examples of layered film include metal-insulator-semiconductor, and metal-insulator-metal.

The organometallic compound precursors can be employed in atomic layer deposition, chemical vapor deposition or, more specifically, in metalorganic chemical vapor deposition processes known in the art. For instance, the organometallic compound precursors described above can be used in atmospheric, as well as in low pressure, chemical vapor deposition processes. The compounds can be employed in hot wall chemical vapor deposition, a method in which the entire reaction chamber is heated, as well as in cold or warm wall type chemical vapor deposition, a technique in which only the substrate is being heated.

The organometallic compound precursors described above also can be used in plasma or photo-assisted chemical vapor deposition processes, in which the energy from a plasma or electromagnetic energy, respectively, is used to activate the chemical vapor deposition precursor. The compounds also can be employed in ion-beam, electron-beam assisted chemical vapor deposition processes in which, respectively, an ion beam or electron beam is directed to the substrate to supply energy for decomposing a chemical vapor deposition precursor. Laser-assisted chemical vapor deposition processes, in which laser light is directed to the substrate to affect photolytic reactions of the chemical vapor deposition precursor, also can be used.

The deposition method can be conducted in various chemical vapor deposition reactors, such as, for instance, hot or cold-wall reactors, plasma-assisted, beam-assisted or laser-assisted reactors, as known in the art.

Illustrative substrates useful in the deposition chamber include, for example, materials selected from a metal, a metal silicide, a semiconductor, an insulator, a barrier material, ceramics and graphite. A preferred substrate is a patterned wafer. Examples of substrates that can be coated employing the deposition method include solid substrates such as metal substrates, e.g., Al, Ni, Ti, Co, Pt, Ta; metal silicides, e.g., TiSi₂, CoSi₂, NiSi₂; semiconductor materials, e.g., Si, SiGe, GaAs, InP, diamond, GaN, SiC; insulators, e.g., SiO₂, Si₃N₄, HfO₂, Ta₂O₅, Al₂O₃, barium strontium titanate (BST); barrier materials, e.g., TiN, TaN; or on substrates that include combinations of materials. In addition, films or coatings can be formed on glass, ceramics, plastics, thermoset polymeric materials, and on other coatings or film layers. In a preferred embodiment, film deposition is on a substrate used in the manufacture or processing of electronic components. In other embodiments, a substrate is employed to support a low resistivity conductor deposit that is stable in the presence of an oxidizer at high temperature or an optically transmitting film.

The deposition method can be conducted to deposit a film on a substrate that has a smooth, flat surface. In an embodiment, the method is conducted to deposit a film on a substrate used in wafer manufacturing or processing. For instance, the method can be conducted to deposit a film on patterned substrates that include features such as trenches, holes or vias. Furthermore, the deposition method also can be integrated with other steps in wafer manufacturing or processing, e.g., masking, etching and others.

Chemical vapor deposition films can be deposited to a desired thickness. For example, films formed can be less than 1 micron thick, preferably less than 500 nanometers and more preferably less than 200 nanometers thick. Films that are less than 50 nanometers thick, for instance, films that have a thickness between about 0.1 and about 20 nanometers, also can be produced.

Organometallic compound precursors described above also can be employed in the method of the invention to form films by atomic layer deposition or atomic layer nucleation techniques, during which a substrate is exposed to alternate pulses of precursor, oxidizer and inert gas streams. Sequential layer deposition techniques are described, for example, in U.S. Pat. No. 6,287,965 and in U.S. Pat. No. 6,342,277. The disclosures of both patents are incorporated herein by reference in their entirety.

For example, in one atomic layer deposition cycle, a substrate is exposed, in step-wise manner, to: a) an inert gas; b) inert gas carrying precursor vapor; c) inert gas; and d) oxidizer, alone or together with inert gas. In general, each step can be as short as the equipment will permit (e.g. milliseconds) and as long as the process requires (e.g. several seconds or minutes). The duration of one cycle can be as short as milliseconds and as long as minutes. The cycle is repeated over a period that can range from a few minutes to hours. Film produced can be a few nanometers thin or thicker, e.g., 1 millimeter (mm).

The means and method of this invention thus achieves a substantial advance in the art, in the provision of a system for supply and dispensing of a vapor or liquid phase reagent, which permits 95-98% of the volume of the originally furnished source chemical to be utilized in the application for which the vapor or liquid phase reagent is selectively dispensed. The ease of cleaning of the two-part ampoule allows for re-use of these ampoules beyond what may be attained with the one-part ampoules.

Correspondingly, in operations such as the manufacture of semiconductor and superconductor products, it is possible with the means and method of this invention to reduce the waste of the source chemical to levels as low as 2-5% of the volume originally loaded into the dispensing vessel, and to re-use the ampoules many times over.

Accordingly, the practice of this invention markedly improves the economics of the source chemical supply and vapor or liquid phase reagent dispensing system, and the process in which the dispensed vapor or liquid phase reagent is employed. The invention in some instances may permit the cost-effective utilization of source chemicals which were as a practical matter precluded by the waste levels characteristic of prior art practice.

As a further benefit of this invention, the reduced source chemical inventory in the vessel at the end of the vapor or liquid phase reagent dispensing operation permits the switch-over time, during which the exhausted supply vessel is changed out from the process system, and replaced with another vessel for further processing, to be minimized as a result of the greater on-stream time for the supply vessel owing to increased usage of the originally charged liquid therefrom, relative to such prior practice.

Various modifications and variations of this invention will be obvious to a worker skilled in the art and it is to be understood that such modifications and variations are to be included within the purview of this application and the spirit and scope of the claims.

While it has been shown and described what is considered to be certain embodiments of the invention, it will, of course, be understood that various modifications and changes in form or detail can readily be made without departing from the spirit and scope of the invention. It is, therefore, intended that this invention not be limited to the exact form and detail herein shown and described, nor to anything less than the whole of the invention herein disclosed and hereinafter claimed.

1. An integrated vapor phase reagent dispensing apparatus comprising:
a plurality of vessels, each vessel comprising a top wall member, a sidewall member and a bottom wall member configured to form an internal vessel compartment to hold a source chemical; and a portion of the top wall member having a vapor phase reagent outlet opening through which a vapor phase reagent can be dispensed from said vessel;
a plurality of vapor phase reagent delivery manifolds, each of said vapor phase reagent delivery manifolds interconnected with each other; each vessel connected to at least one vapor phase reagent delivery manifold; each vapor phase reagent delivery manifold comprising a vapor phase reagent discharge line; and said vapor phase reagent discharge line extending from the vapor phase reagent outlet opening upwardly and exteriorly from the top wall member for removal of vapor phase reagent from said vessel, the vapor phase reagent discharge line optionally containing one or more vapor phase reagent flow control valves therein for control of flow of the vapor phase reagent therethrough; and
one or more controllers for directing communication with each of said vapor phase reagent delivery manifolds and each of said vessels, in such a way that each of said vapor phase reagent delivery manifolds are operable independently of one another, and each of said vessels are operable independently of one another.

2. The integrated vapor phase reagent dispensing apparatus of claim 1 further comprising a plurality of carrier gas feed manifolds, each of said carrier gas feed manifolds connected to at least one vapor phase reagent delivery manifold; each carrier gas feed manifold comprising a carrier gas feed line; the carrier gas feed line containing one or more carrier gas flow control valves therein for control of flow of the carrier gas therethrough, and a pressure transducer for monitoring and controlling the pressure of the carrier gas feed manifold.

3. The integrated vapor phase reagent dispensing apparatus of claim 2 further comprising:
a deposition chamber selected from a chemical vapor deposition chamber and an atomic layer deposition chamber;
the vapor phase reagent discharge line connecting the integrated vapor phase reagent dispensing apparatus to the deposition chamber;
optionally a heatable susceptor contained within the deposition chamber and located in a receiving relationship to the vapor phase reagent discharge line; and
an effluent discharge line connected to the deposition chamber;
such that vapor phase reagent passes through the vapor phase reagent discharge line and into the deposition chamber, for contact with a substrate, optionally on the heatable susceptor, and any remaining effluent is discharged through the effluent discharge line.

4. The integrated vapor phase reagent dispensing apparatus of claim 3 wherein said controller has an algorithm for directing communication with each of said carrier gas feed manifolds, each of said vapor phase reagent delivery manifolds, each of said vessels, and said deposition chamber, in such a way that each of said carrier gas feed manifolds are operable independently of one another, each of said vapor phase reagent delivery manifolds are operable independently of one another, and each of said vessels are operable independently of one another.

5. The integrated vapor phase reagent dispensing apparatus of claim 3 wherein said controller receives digital and analog inputs from each of said carrier gas feed manifolds, each of said vapor phase reagent delivery manifolds, and each of said vessels, and uses said digital and analog inputs to perform operations.

6. The integrated vapor phase reagent dispensing apparatus of claim 3 wherein said controller receives command inputs from said deposition chamber, and uses said command inputs to perform operations.

7. The integrated vapor phase reagent dispensing apparatus of claim 5 wherein said operations comprise controlling temperature in separate temperature zones in each of said vapor phase reagent delivery manifolds, each of said vessels, and each of said carrier gas feed manifolds; controlling valves in each of said vapor phase reagent delivery manifolds and each of said carrier gas feed manifolds; monitoring thermocouples and valve position indicators for feedback in each of said vapor phase reagent delivery manifolds, each of said vessels, and each of said carrier gas feed manifolds; relaying electric and pneumatic valve actuation signals from the deposition chamber to each of said active vapor phase reagent delivery manifolds and each of said active carrier gas feed manifolds; and communicating with said deposition chamber involving emergency gas off (EGO) of cabinet, temperature warnings, temperature alarms, valve position information, level sensor information and other alarms.

8. The integrated vapor phase reagent dispensing apparatus of claim 6 wherein said operations comprise controlling temperature in separate temperature zones in each of said vapor phase reagent delivery manifolds, each of said carrier gas feed manifolds, and each of said vessels; controlling valves in each of said vapor phase reagent delivery manifolds and each of said carrier gas feed manifolds; monitoring thermocouples and valve position indicators for feedback in each of said vapor phase reagent delivery manifolds, each of said vessels, and each of said carrier gas feed manifolds; relaying electric and pneumatic valve actuation signals from the deposition chamber to each of said active vapor phase reagent delivery manifolds and each of said active carrier gas feed manifolds; and communicating with said deposition chamber involving emergency gas off (EGO) of cabinet, temperature warnings, temperature alarms, valve position information, level sensor information and other alarms.

9. The integrated vapor phase reagent dispensing apparatus of claim 3 wherein said controller comprises a programmable logic controller.

10. The integrated vapor phase reagent dispensing apparatus of claim 5 wherein said controller relays said digital and analog inputs to a computer, allowing a user to monitor said operations.

11. The integrated vapor phase reagent dispensing apparatus of claim 6 wherein said controller relays said command inputs to a computer, allowing a user to monitor said operations.

12. The integrated vapor phase reagent dispensing apparatus of claim 1 wherein each of said vessels includes at least one source chemical level sensor and at least one temperature sensor, said controller directing communication with each of the source chemical level sensors and each of the temperature sensors to operate each of said carrier gas feed manifolds independently of one another, each of said vapor phase reagent delivery manifolds independently of one another, and each of said vessels independently of any other of said vessels.

13. The integrated vapor phase reagent dispensing apparatus of claim 1 further comprising the vapor phase reagent discharge line in vapor phase reagent flow communication with a vapor phase delivery deposition system, said deposition system selected from a chemical vapor deposition system and an atomic layer deposition system.

14. The integrated vapor phase reagent dispensing apparatus of claim 1 wherein the source chemical comprises a liquid or solid precursor for a metal selected from Group 2, Group 3, Group 4, Group 5, Group 6, Group 7, Group 8, Group 9, Group 10, Group 11, Group 12, Group 13, Group 14, Group 15, Group 16, the Lanthanide series and the Actinide series of the Periodic Table.

15. The integrated vapor phase reagent dispensing apparatus of claim 1 wherein the vapor phase reagent comprises a vapor phase precursor for a metal selected from Group 2, Group 3, Group 4, Group 5, Group 6, Group 7, Group 8, Group 9, Group 10, Group 11, Group 12, Group 13, Group 14, Group 15, Group 16, the Lanthanide series and the Actinide series of the Periodic Table.

16. The integrated vapor phase reagent dispensing apparatus of claim 3 wherein said substrate is comprised of a material selected from a metal, a metal silicide, a semiconductor, an insulator and a barrier material.

17. A method for delivery of a vapor phase reagent to a deposition chamber comprising:
(a) providing an integrated vapor phase reagent dispensing apparatus comprising:
a plurality of vessels, each vessel comprising a top wall member, a sidewall member and a bottom wall member configured to form an internal vessel compartment to hold a source chemical; and a portion of the top wall member having a vapor phase reagent outlet opening through which a vapor phase reagent can be dispensed from said vessel;
a plurality of vapor phase reagent delivery manifolds, each of said vapor phase reagent delivery manifolds interconnected with each other; each vessel connected to at least one vapor phase reagent delivery manifold; each vapor phase reagent delivery manifold comprising a vapor phase reagent discharge line; and
said vapor phase reagent discharge line extending from the vapor phase reagent outlet opening upwardly and exteriorly from the top wall member for removal of vapor phase reagent from said vessel, the vapor phase reagent discharge line optionally containing one or more vapor phase reagent flow control valves therein for control of flow of the vapor phase reagent therethrough;
a plurality of carrier gas feed manifolds; each carrier gas feed manifold connected to at least one vapor phase reagent delivery manifold; each carrier gas feed manifold comprising a carrier gas feed line; the carrier gas feed line containing one or more carrier gas flow control valves therein for control of flow of a carrier gas therethrough, and a pressure transducer for monitoring and controlling the pressure of the carrier gas feed manifold; and
one or more controllers for directing communication with each of said carrier gas feed manifolds, each of said vapor phase reagent delivery manifolds and each of said vessels, in such a way that each of said carrier gas feed manifolds are operable independently of one another, each of said vapor phase reagent delivery manifolds are operable independently of one another, and each of said vessels are operable independently of one another;
(b) adding source chemical to one or more of said vessels;
(c) optionally heating the source chemical in one or more of said vessels to a temperature sufficient to vaporize the source chemical to provide vapor phase reagent;
(d) withdrawing the vapor phase reagent from one of said vessels, independently of any other of said vessels, through said vapor phase reagent discharge line;
(e) feeding a carrier gas into one or more of said vapor phase reagent delivery manifolds through said carrier gas feed line to mix with said vapor phase reagent; and
(f) feeding the vapor phase reagent and carrier gas into said deposition chamber.

18. The method of claim 17 further comprising:
(g) contacting the vapor phase reagent with a substrate, optionally on a heatable susceptor, within the deposition chamber; and
(h) discharging any remaining effluent through an effluent discharge line connected to the deposition chamber.

19. The method of claim 17 further comprising detecting a low level of source chemical in at least one of said vessels and exchanging said low level vessel.

20. The method of claim 17 further comprising, simultaneously with dispensing said vapor phase reagent from one of said vessels and carrier gas from one of said carrier gas feed manifolds into said deposition chamber, disconnecting another vessel containing a low level of source chemical from said integrated vapor phase reagent dispensing apparatus, refilling said vessel, and replacing said vessel in said integrated vapor phase reagent dispensing apparatus.
